(19) United States
(12) Patent Application Publication
(10) Pub. No.: US 2026/0182213 A1
(43) Pub. Date: Jun. 25, 2026

(54) DISPLAY DEVICE

(71) Applicant: LG Display Co., Ltd., Seoul (KR)

(72) Inventors: JongWoo PARK, Goyang-si (KR); KwanSoo KIM, Seoul (KR)

(73) Assignee: LG Display Co., Ltd., Seoul (KR)

(21) Appl. No.: 19/222,785

(22) Filed: May 29, 2025

(30) Foreign Application Priority Data
Dec. 24, 2024 (KR) 10-2024-0196063

(51) Int. Cl. H10K 59/80; H10K 59/122

(52) U.S. Cl. CPC H10K 59/873; H10K 59/122; H10K 59/80515

(57) ABSTRACT

A display device may include a normal area having a first light-emitting area, an optical area surrounded by the normal area and having a second light-emitting area and a transmissive area, a planarization layer in the normal area and the optical area, a first light-emitting element on the planarization layer in the first light-emitting area and having a first electrode, a first organic layer on the first electrode, and a second electrode on the first organic layer, and a second light-emitting element on the planarization layer in the second light-emitting area and having a third electrode, a second organic layer on the third electrode, and a fourth electrode on the second organic layer. The fourth electrode includes at least one first convex area or at least one first concave area in the second light-emitting area. Therefore, it can improve light extraction efficiency in the optical area.

### CROSS-REFERENCE TO RELATED APPLICATIONS

This application claims the benefit of and priority to Korean Patent Application No. 10-2024-0196063 filed on Dec. 24, 2024, in the Korean Intellectual Property Office, the entire contents of which are incorporated herein by reference for all purposes.

### BACKGROUND

### 1. Technical Field

The present disclosure relates to a display device, and more particularly to, for example, without limitation, a display device in which luminous efficiency of an area in which an electronic optical device is disposed is improved.

### 2. Description of Related Art

Display devices, which visually display electrical information signals, are being rapidly developed. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

Recently, the multimedia functions of mobile terminals have been improved. For example, a display device basically equipped with an electronic optical device, such as a camera or sensor, embedded in a front surface of the display device has been developed. However, the camera or sensor disposed on the front surface of the display device may restrict a screen design. The display device adopts a design including a notch or punch hole to reduce a space occupied by the camera or sensor disposed on the front surface of the display device. However, a screen size is still restricted, which makes it difficult to implement a full-screen display.

To implement the full-screen display, there has been proposed a configuration in which an area, in which low-resolution pixels are disposed, is provided in a screen of a display device, and a camera and/or various types of sensors are disposed in the area in which the low-resolution pixels are disposed.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure is to provide a display device in which luminous efficiency is improved and luminance is increased in a light-emitting area in which an electronic optical device, such as a camera or sensor, is disposed and a light-emitting area in which no electronic optical device is disposed.

Another aspect of the present disclosure is to provide a display device a degradation of the light-emitting element may be suppressed and a lifespan of the light-emitting element may be improved in a light-emitting area in which an electronic optical device, such as a camera or sensor, is disposed and a light-emitting area in which no electronic optical device is disposed.

Aspects of the present disclosure are not limited to the above-mentioned aspects, and other aspects, which are not mentioned above, can be clearly understood by those skilled in the art from the following descriptions.

According to an aspect of the present disclosure, there is provided a display device. The display device includes a substrate, a normal area comprising a first light-emitting area, an optical area surrounded by the normal area and comprising a second light-emitting area and a transmissive area, a planarization layer disposed on the substrate and disposed in the normal area and the optical area, a first light-emitting element disposed on the planarization layer in the first light-emitting area and comprising a first electrode, a first organic layer disposed on the first electrode, and a second electrode disposed on the first organic layer and a second light-emitting element disposed on the planarization layer in the second light-emitting area and comprising a third electrode, a second organic layer disposed on the third electrode, and a fourth electrode disposed on the second organic layer. The display device includes the fourth electrode of the second light-emitting element comprises at least one first convex area or at least one first concave area in the second light-emitting area.

Other detailed matters of the example embodiments are included in the detailed description and the drawings.

According to the embodiment of the present disclosure, at least one convex area or at least one concave area is disposed in the light-emitting area in which the electronic optical device, such as a camera or sensor, is disposed and the light-emitting area in which no electronic optical device is disposed, such that light extraction efficiency of the light-emitting element may be improved, and the display device may operate with low power consumption in terms of a reduction in power consumption.

According to the embodiment of the present disclosure, the structure for improving the luminous efficiency is provided in the light-emitting area in which the electronic optical device, such as a camera or sensor, is disposed and the light-emitting area in which no electronic optical device is disposed, such that a degradation of the light-emitting element may be suppressed, and the lifespan may be improved.

The effects of the present disclosure are not limited to the aforementioned effects, and other effects, which are not mentioned above, will be apparently understood to a person having ordinary skill in the art from the following description.

The aspects of the present disclosure, the means for achieving the aspects, and the effects of the present disclosure described above do not specify essential features of the claims, and, thus, the scope of the claims is not limited to the disclosure of the present disclosure.

Aspects of the present disclosure are not limited to the above-mentioned aspects, and other aspects, which are not mentioned above, can be clearly understood by those skilled in the art from the following descriptions.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIGS. 1A to 1D are schematic top plan views of a display device according to an embodiment of the present disclosure;

FIG. 2 is a system configuration view of the display device according to the embodiment of the present disclosure;

FIG. 3 is an equivalent circuit diagram of a subpixel of the display panel according to the embodiment of the present disclosure;

FIG. 4 is a view illustrating an example in which the subpixels are disposed in a display area according to the embodiment of the present disclosure;

FIG. 5A is a view illustrating an example in which signal lines are disposed in a first optical area and a normal area according to the embodiment of the present disclosure;

FIG. 5B is a view illustrating an example in which the signal lines are disposed in a second optical area and the normal area according to the embodiment of the present disclosure;

FIG. 6 is a top plan view illustrating the normal area of the display device according to the embodiment of the present disclosure;

FIG. 7 is a cross-sectional view taken along line A-B in FIG. 6;

FIG. 8 is a top plan view schematically illustrating the first optical area of the display device according to the embodiment of the present disclosure;

FIG. 9 is a cross-sectional view taken along line C-D in FIG. 8;

FIG. 10 is a cross-sectional view illustrating a first optical area of a display device according to another embodiment of the present disclosure;

FIG. 11 is a top plan view illustrating a normal area of a display device according to still another embodiment of the present disclosure;

FIG. 12 is a cross-sectional view taken along line E-F in FIG. 11;

FIG. 13 is a top plan view schematically illustrating a first optical area of a display device according to yet another embodiment of the present disclosure;

FIG. 14 is a cross-sectional view taken along line L-M in FIG. 13;

FIG. 15 is a top plan view illustrating a normal area of a display device according to still yet another embodiment of the present disclosure;

FIG. 16 is a cross-sectional view taken along line G-H in FIG. 15;

FIG. 17 is a top plan view schematically illustrating a first optical area of a display device according to a further embodiment of the present disclosure;

FIG. 18 is a cross-sectional view taken along line I-J in FIG. 17;

FIG. 19 is a cross-sectional view schematically illustrating shapes of a plurality of protrusions applied to a display device according to another further embodiment of the present disclosure; and

FIGS. 20 and 21 are views illustrating arrangement states of a plurality of patterns, a plurality of convex areas, or a plurality of protrusions disposed in a light-emitting area of a display device according to still another further embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

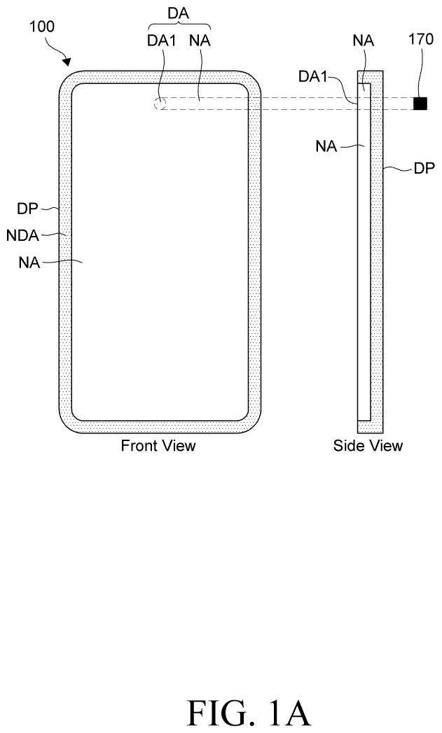

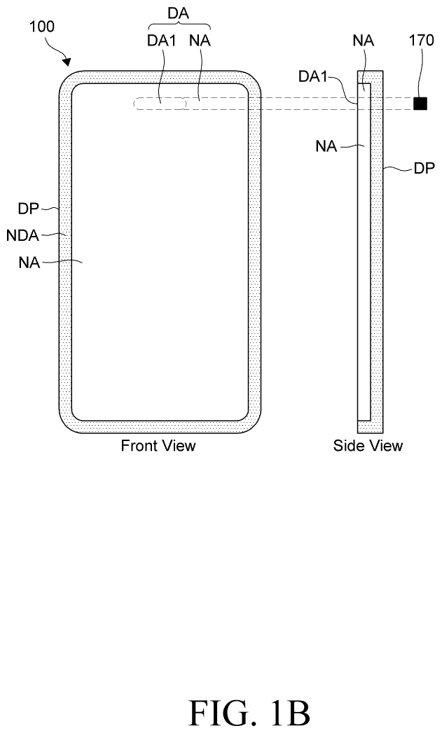

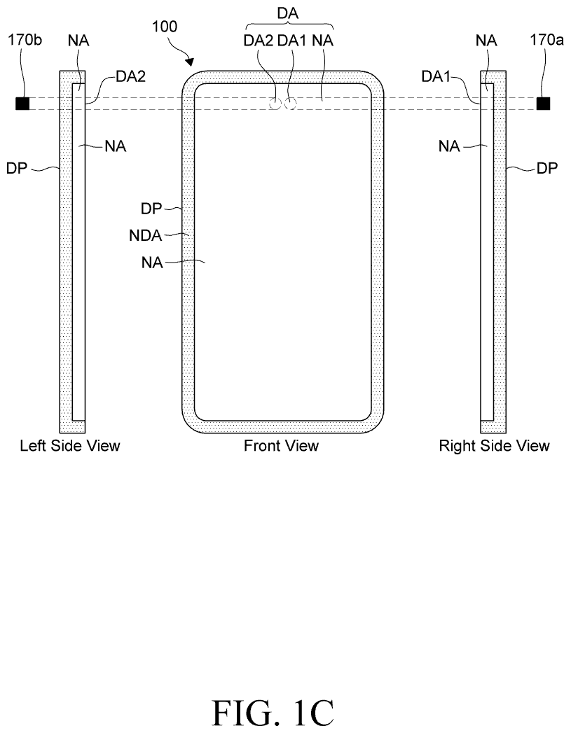

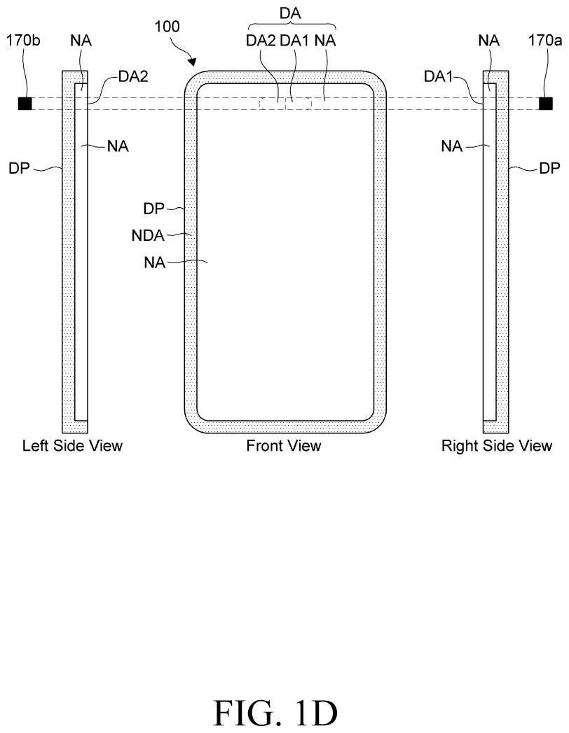

FIGS. 1A to 1D are schematic top plan views of a display device according to an embodiment of the present disclosure.

With reference to FIGS. 1A to 1D, a display device 100 according to an embodiment of the present disclosure may include a display panel DP configured to display images, and one or more electronic optical devices 170, 170a, and 170b. The electronic optical devices 170, 170a, and 170b may each include a light-receiving device, such as a camera or sensor, that receives light.

The display panel DP is a panel configured to display images to a user.

The display panel DP may include a display element configured to display images, a driving element configured to operate the display element, and lines configured to transmit various types of signals to the display element and the driving element. Different display elements may be defined depending on the types of display panels DP. For example, in a case in which the display panel DP is an organic light-emitting display panel, the display element may be an organic light-emitting element including a first electrode (an anode or a cathode), an organic layer, and a second electrode (a cathode or an anode).

For example, in a case in which the display panel DP is a liquid crystal display panel, the display element may be a liquid crystal display element. In addition, the display device 100 according to the embodiment of the present disclosure may be a flexible display device.

Hereinafter, it is assumed that the display panel DP is the organic light-emitting display panel. However, the display panel DP is not limited to the organic light-emitting display panel.

Meanwhile, the display panel DP may include a substrate, and a plurality of insulation films, transistor layers, and light-emitting element layers disposed on the substrate.

To display images, the display panel DP may include a plurality of subpixels, and various types of signal lines configured to operate the plurality of subpixels.

The display panel DP may include a display area DA in which images are displayed, and a non-display area NDA in which no image is displayed.

The display area DA may include a plurality of subpixels configured to constitute a plurality of pixels, and a circuit configured to operate the plurality of subpixels. The plurality of subpixels is minimum units that constitute the display area DA. The display element may be disposed in each of the plurality of subpixels. The plurality of subpixels may constitute the pixel.

For example, the organic light-emitting element including the first electrode, the organic layer, and the second electrode may be disposed in each of the plurality of subpixels. However, the present disclosure is not limited thereto.

In addition, the circuit configured to operate the plurality of subpixels may include driving elements, lines, and the like. For example, the circuit may include a thin-film transistor, a storage capacitor, a gate line, a data line, and the like. However, the present disclosure is not limited thereto.

The non-display area NDA may be bent, such that the non-display area NDA is not visible from a front surface. The non-display area NDA may be covered by a casing (not illustrated). The non-display area NDA is called a bezel area.

Various lines and circuits for operating the organic light-emitting element in the display area DA may be disposed in the non-display area NDA.

For example, the non-display area NDA may include link lines for transmitting signals to the plurality of subpixels and the circuit in the display area DA. The non-display area NDA may include gate-in-panel (GIP) lines or drive ICs such as gate driver ICs and data driver ICs. However, the present disclosure is not limited thereto.

FIGS. 1A to 1D illustrate that the non-display area NDA surrounds the display area DA having a quadrangular shape. However, the shapes and arrangements of the display area DA and the non-display area NDA are not limited to the example illustrated in FIGS. 1A to 1D. The display area DA and the non-display area NDA may be suitable for the design of an electronic device equipped with the display device 100. For example, an example shape of the display area DA may also be a pentagonal shape, a hexagonal shape, a circular shape, an elliptical shape, or the like.

The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

With reference to FIGS. 1A to 1D, in the display device 100 according to the embodiments of the present disclosure, the one or more electronic optical devices 170, 170a, and 170b are electronic components positioned at a lower side (a side opposite to a visual surface) of the display panel DP.

The light may enter the front surface (visual surface) of the display panel DP, passes through the display panel DP, and then propagate to the one or more electronic optical devices 170, 170a, and 170b positioned at the lower side (the side opposite to the visual surface) of the display panel DP.

The one or more electronic optical devices 170, 170a, and 170b may be devices that receive the light having passed through the display panel DP and perform predetermined functions in response to the received light.

For example, the electronic optical devices 170, 170a, and 170b may include any one or more of an image capturing device, such as a camera (image sensor), and a detection sensor, such as a proximity sensor and an illuminance sensor.

With reference to FIGS. 1A to 1D, in the display device 100 according to the embodiments of the present disclosure, the display area DA may include a normal area NA and one or more optical areas DA1 and DA2.

The one or more optical areas DA1 and DA2 may be areas that overlap the one or more electronic optical devices 170, 170a, and 170b.

According to the example in FIG. 1A, the display area DA may include the normal area NA and a first optical area DA1. In this case, at least a part of the first optical area DA1 may overlap a first electronic optical device 170.

FIG. 1A illustrates that the first optical area DA1 has a circular structure. However, the shape of the first optical area DA1 according to the embodiment of the present disclosure is not limited thereto. For example, as illustrated in FIG. 1B, the shape of the first optical area DA1 may be an octagonal shape or various polygonal shapes.

According to the example in FIG. 1C, the display area DA may include the normal area NA, the first optical area DA1, and a second optical area DA2. In the example in FIG. 1C, the normal area NA may be present between the first optical area DA1 and the second optical area DA2. In this case, at least a part of the first optical area DA1 may overlap the first electronic optical device 170a, and at least a part of the second optical area DA2 may overlap the second electronic optical device 170b.

According to the example in FIG. 1D, the display area DA may include the normal area NA, the first optical area DA1, and the second optical area DA2. In the example in FIG. 1D, the normal area NA is not present between the first optical area DA1 and the second optical area DA2. That is, the first optical area DA1 and the second optical area DA2 may adjoin each other. In this case, at least a part of the first optical area DA1 may overlap the first electronic optical device 170a, and at least a part of the second optical area DA2 may overlap the second electronic optical device 170b.

The one or more optical areas DA1 and DA2 each need to have both an image display structure and a light transmission structure.

That is, because the one or more optical areas DA1 and DA2 are partial areas of the display area DA, the subpixels for displaying images need to be disposed in the one or more optical areas DA1 and DA2. The one or more optical areas DA1 and DA2 each need to have the light transmission structure for transmitting light to the one or more electronic optical devices 170, 170a, and 170b.

The one or more electronic optical devices 170, 170a, and 170b are devices that need to receive light. However, the one or more electronic optical devices 170, 170a, and 170b are positioned at a rear side (the lower side, i.e., the side opposite to the visual surface) of the display panel DP and receive the light having passed through the display panel DP.

The one or more electronic optical devices 170, 170a, and 170b are not exposed to the front surface (visual surface) of the display panel DP. Therefore, the user does not visually recognize the electronic optical devices 170, 170a, and 170b when the user looks at the front surface of the display device 100.

For example, the first electronic optical device 170 (170a) may be a camera, and the second electronic optical device 170b may be a detection sensor such as a proximity sensor or an illuminance sensor. For example, the detection sensor may be an infrared sensor that detects infrared rays.

On the contrary, the first electronic optical device 170 (170a) may be a detection sensor, and the second electronic optical device 170b may be a camera.

Hereinafter, for convenience of description, an example will be described in which the first electronic optical device 170 (170a) is a camera, and the second electronic optical device 170b is a detection sensor. In this case, the camera may be a camera lens or an image sensor.

In case that the first electronic optical device 170 (170a) is a camera, the camera may be positioned at the rear side (lower side) of the display panel DP. However, the camera may be the front surface camera configured to capture an image of an object disposed forward of the display panel DP. Therefore, the user may capture an image by using the camera, which is not visible from the visual surface, while looking at the visual surface of the display panel DP.

The normal area NA and the one or more optical areas DA1 and DA2, which are included in the display area DA, are areas in which images may be displayed. However, the normal area NA is an area that does not require the light transmission structure, and the one or more optical areas DA1 and DA2 are areas that need to have the light transmission structures.

Therefore, the one or more optical areas DA1 and DA2 each need to have transmittance at a predetermined level or higher. The normal area NA may not have optical transmittance or have low transmittance at less than the predetermined level.

For example, the one or more optical areas DA1 and DA2 and the normal area NA may be different in resolution, subpixel arrangement structure, number of subpixels per unit area, electrode structure, line structure, electrode arrangement structure, line arrangement structure, or the like.

For example, the number of subpixels per unit area in each of the one or more optical areas DA1 and DA2 may be smaller than the number of subpixels per unit area in the normal area NA. That is, the resolution in each of the one or more optical areas DA1 and DA2 may be lower than the resolution in the normal area NA. In this case, the number of subpixels per unit area may be a criterion for measuring the resolution and may also be referred to as PPI (pixels per inch) that means the number of pixels within 1 inch.

For example, the number of subpixels per unit area in the first optical area DA1 may be smaller than the number of subpixels per unit area in the normal area NA. In addition, the number of subpixels per unit area in the second optical area DA2 may be equal to or larger than the number of subpixels per unit area in the first optical area DA1.

The first optical area DA1 may have various shapes such as a circular shape, an elliptical shape, a quadrangular shape, a hexagonal shape, or an octagonal shape. The second optical area DA2 may have various shapes such as a circular shape, an elliptical shape, a quadrangular shape, a hexagonal shape, or an octagonal shape. The first optical area DA1 and the second optical area DA2 may have the same shape or different shapes.

With reference to FIG. 1C, in case that the first optical area DA1 and the second optical area DA2 adjoin each other, an overall optical area including the first optical area DA1 and the second optical area DA2 may have various shapes such as a circular shape, an elliptical shape, a quadrangular shape, a hexagonal shape, or an octagonal shape.

Hereinafter, for convenience of description, an example will be described in which the first optical area DA1 and the second optical area DA2 each have a circular shape.

In the display device 100 according to the embodiment of the present disclosure, in case that the first electronic optical device 170 (170a), which is hidden at the lower side of the display panel DP without being exposed to the outside, is a camera, the display device 100 according to the embodiment of the present disclosure may be a display to which an under-display camera (UDC) technology is applied.

According to this configuration, in the display device 100 according to the embodiment of the present disclosure, a notch or camera hole for exposing a camera need not be formed in the display panel DP, such that an area of the display area DA does not decrease.

Therefore, because the notch or camera hole for exposing the camera need not be formed in the display panel DP, a size of a bezel area may decrease, and a design constraint may be eliminated, such that a degree of freedom may increase.

In the display device 100 according to the embodiment of the present disclosure, even though the one or more electronic optical devices 170, 170a, and 170b are positioned to be hidden at the rear side of the display panel DP, the one or more electronic optical devices 170, 170a, and 170b need to normally receive light and normally perform the predetermined functions.

In addition, in the display device 100 according to the embodiment of the present disclosure, even though the one or more electronic optical devices 170, 170a, and 170b are positioned to be hidden at the rear side of the display panel DP and positioned to overlap the display area DA, images need to be normally displayed in the one or more optical areas DA1 and DA2 that overlap the one or more electronic optical devices 170, 170a, and 170b in the display area DA.

Therefore, the display device 100 according to the embodiment of the present disclosure may have a structure capable of improving the transmittance of the first optical area DA1 and the second optical area DA2 that overlap the electronic optical devices 170, 170a, and 170b.

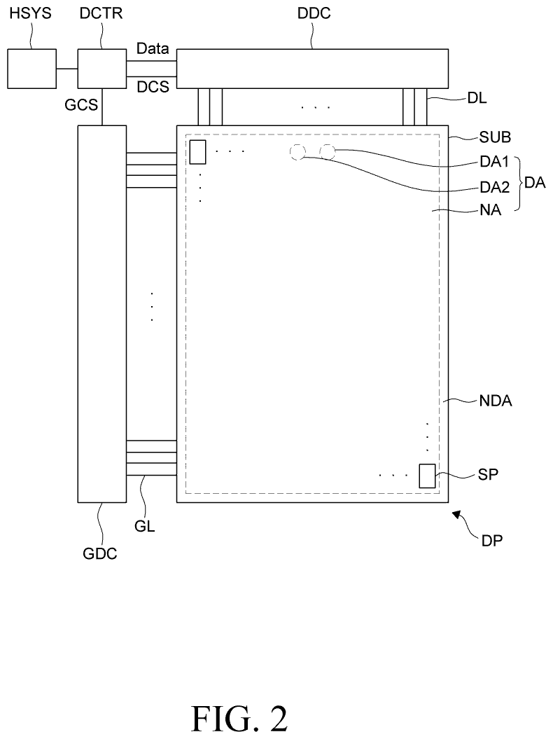

FIG. 2 is a system configuration view of the display device according to the embodiment of the present disclosure.

With reference to FIG. 2, the display device 100 may include the display panel DP and a display drive circuit that are constituent elements for displaying images. The display drive circuit may be a circuit for operating the display panel DP and include a data drive circuit DDC, a gate drive circuit GDC, and a display controller DCTR.

The display panel DP may include a display area DA in which images are displayed, and a non-display area NDA in which no image is displayed.

The non-display area NDA may be an outer peripheral area of the display area DA and also referred to as a bezel area. The entirety or a part of the non-display area NDA may be an area visible from the front surface of the display device 100 or an area that is bent and not visible from the front surface of the display device 100.

The display panel DP may include a substrate SUB, and a plurality of subpixels SP disposed on the substrate SUB. In addition, the display panel DP may further include various types of signal lines to operate the plurality of subpixels SP.

The structure of each of the plurality of subpixels SP may vary depending on the type of display device 100. For example, in case that the display device 100 is a spontaneous light-emitting display device having the subpixel SP that autonomously emits light, the subpixels SP may each include a light-emitting element configured to autonomously emit light, one or more transistors, and one or more capacitors.

Various types of signal lines may include a plurality of data lines DL configured to transmit data signals (also referred to as data voltages or image signals), and a plurality of gate lines GL configured to transmit gate signals (also referred to as scan signals).

The plurality of data lines DL and the plurality of gate lines GL may intersect one another. The plurality of data lines DL may each be disposed while extending in a first direction. The plurality of gate lines GL may each be disposed while extending in a second direction. In this case, the first direction may be a column direction, and the second direction may be a row direction. Alternatively, the first direction may be a row direction, and the second direction may be a column direction.

The data drive circuit DDC may be a circuit for operating the plurality of data lines DL and output data signals to the plurality of data lines DL. The gate drive circuit GDC may be a circuit for operating the plurality of gate lines GL and output gate signals to the plurality of gate lines GL.

The display controller DCTR may be a device for controlling the data drive circuit DDC and the gate drive circuit GDC and may control driving timing for the plurality of data lines DL and driving timing for the plurality of gate lines GL.

The display controller DCTR may supply a data drive control signal DCS to the data drive circuit DDC to control in order to control the data drive circuit DDC and supply a gate drive control signal GCS to the gate drive circuit GDC in order to control the gate drive circuit GDC.

The display controller DCTR may receive input image data from a host system HSYS and supply image data Data to the data drive circuit DDC on the basis of the input image data.

To further provide a touch sensing function in addition to the image display function, the display device 100 according to the embodiments of the present disclosure may include a touch sensor, and a touch sensing circuit configured to sense the touch sensor to detect whether a touch is made by a touch object such as a finger, a pen, or the like or to detect a touch position.

The touch sensing circuit may further include a touch drive circuit configured to operate the touch sensor, sense the touch sensor, and produce and output touch sensing data, and a touch controller configured to use the touch sensing data to detect the occurrence of a touch or a touch position.

The touch sensor may include a plurality of touch electrodes. The touch sensor may further include a plurality of touch lines configured to electrically connect the plurality of touch electrodes and the touch drive circuit.

The touch sensor may be provided in the form of a touch panel disposed outside the display panel DP or provided in the display panel DP.

In case that the touch sensor is provided in the form of a touch panel present outside the display panel DP, the touch sensor is called an externally-carried touch sensor. In case that the touch sensor is an externally-carried touch sensor, the touch panel and the display panel DP may be separately manufactured and coupled to each other during an assembling process. The externally-carried touch panel may include a touch panel substrate, and the plurality of touch electrodes disposed on the touch panel substrate.

In case that the touch sensor is present inside the display panel DP, the touch sensor may be provided on the substrate SUB together with signal lines and electrodes related to a display operation during a process of manufacturing the display panel DP.

The touch drive circuit and the touch controller, which are included in the touch sensing circuit, may be implemented as separate devices or a single device. In addition, the touch drive circuit and the data drive circuit DDC may be implemented as separate devices or a single device.

In addition, the display device 100 may further include a power supply circuit configured to supply various types of power to the display drive circuit and/or the touch sensing circuit.

The display device 100 according to the embodiments of the present disclosure may be a mobile terminal such as a smartphone or a tablet, or a monitor or a television (TV) having various sizes. However, the present disclosure is not limited thereto. The display device 100 may be one of the displays having various types and various sizes and being capable of displaying information or images.

As described above, the display area DA of the display panel DP may include the normal area NA and the one or more optical areas DA1 and DA2.

The normal area NA and the one or more optical areas DA1 and DA2 are areas in which images may be displayed. However, the normal area NA is an area that does not require the light transmission structure, and the one or more optical areas DA1 and DA2 are areas that need to have the light transmission structures.

As described above, the display area DA of the display panel DP may include the normal area NA and the one or more optical areas DA1 and DA2.

Hereinafter, for convenience of description, it is assumed that the display area DA includes both the first optical area DA1 and the second optical area DA2 (FIGS. 1C and 1D).

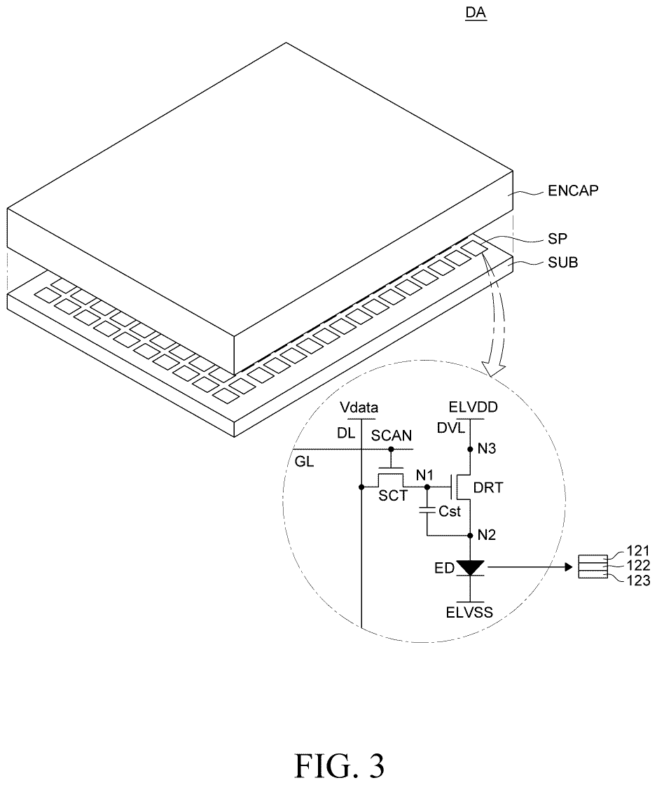

FIG. 3 is an equivalent circuit diagram of a subpixel of the display panel according to the embodiment of the present disclosure.

The subpixels SP, which are disposed in the normal area NA, the first optical area DA1, and the second optical area DA2 included in the display area DA of the display panel DP, may each include a light-emitting element ED, a driving transistor DRT configured to operate the light-emitting element ED, a scan transistor SCT configured to transmit a data voltage VDATA to a first node N1 of the driving transistor DRT, and a storage capacitor Cst configured to maintain a predetermined voltage for one frame.

The driving transistor DRT may include the first node N1 to which the data voltage may be applied, a second node N2 electrically connected to the light-emitting element ED, and a third node N3 to which a drive voltage ELVDD is applied from a drive voltage line DVL. In the driving transistor DRT, the first node N1 may be a gate node, the second node N2 may be a source node or drain node, and the third node N3 may be a drain node or source node.

The light-emitting element ED may include a first electrode 121, a first organic layer 122, and a second electrode 123. The first electrode 121 may be an anode electrode disposed in each of the subpixels SP and electrically connected to the second node N2 of the driving transistor DRT of each of the subpixels SP. The second electrode 123 may be a cathode electrode disposed in common in the plurality of subpixels SP, and a base voltage ELVSS may be applied to the second electrode 123. However, the present disclosure is not limited thereto.

The scan transistor SCT is turned on or off by being controlled in response to a scan signal SCAN that is a gate signal applied through the gate line GL. The scan transistor SCT may be electrically connected between the first node N1 of the driving transistor DRT and the data line DL.

The storage capacitor Cst may be electrically connected between the first node N1 and the second node N2 of the driving transistor DRT.

As illustrated in FIG. 3, the subpixels SP may each have a 2T (transistor) 1C (capacitor) structure including two transistors DRT and SCT and a single capacitor Cst. In some instances, the subpixel SP may further include one or more transistors or further include one or more capacitors.

The driving transistor DRT and the scan transistor SCT may each be an n-type transistor or a p-type transistor.

The circuit element (particularly, the light-emitting element ED) in each of the subpixels SP is vulnerable to outside moisture or oxygen. Therefore, an encapsulation layer ENCAP may be disposed on the display panel DP in order to inhibit outside moisture or oxygen from permeating into the circuit element (particularly, the light-emitting element ED). The encapsulation layer ENCAP may be disposed in a shape that covers the light-emitting elements ED.

Meanwhile, a differential pixel density designing method may be applied as one method of increasing the transmittance of at least one of the first optical area DA1 and the second optical area DA2.

According to the differential pixel density designing method, the display panel DP may be designed so that the number of subpixels per unit area in at least one of the first optical area DA1 and the second optical area DA2 is smaller than the number of subpixels per unit area in the normal area NA.

However, in some instances, alternatively, a differential pixel size designing method may be applied as another method of increasing the transmittance of at least one of the first optical area DA1 and the second optical area DA2.

According to the differential pixel size designing method, the display panel DP may be designed so that the number of subpixels per unit area in at least one of the first optical area DA1 and the second optical area DA2 is equal or similar to the number of subpixels per unit area in the normal area NA, and a size (i.e., light-emitting area size) of each of the subpixels SP disposed in at least one of the first optical area DA1 and the second optical area DA2 is smaller than a size (i.e., light-emitting area size) of each of the subpixels SP disposed in the normal area NA.

Hereinafter, for convenience of description, the description will be made on the assumption that the differential pixel density designing method is applied between the two types of methods (the differential pixel density designing method and the differential pixel size designing method) of increasing the transmittance of at least one of the first optical area DA1 and the second optical area DA2.

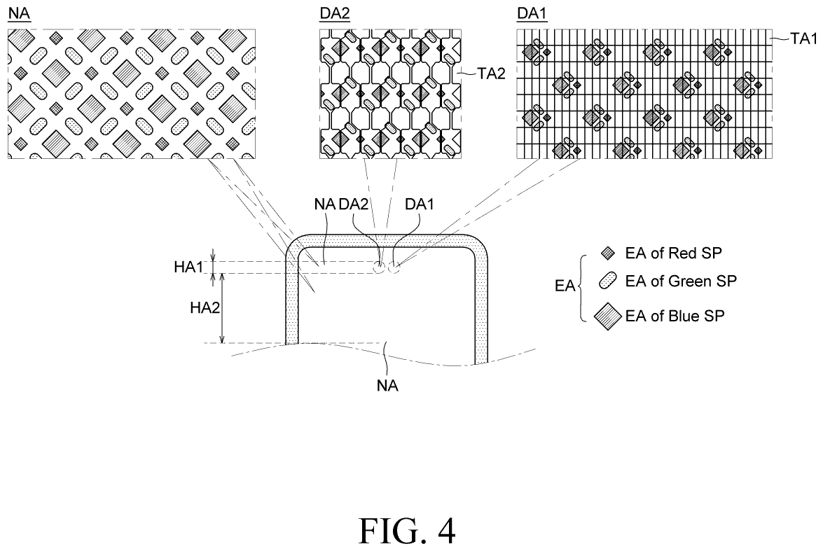

FIG. 4 is a view illustrating an example in which the subpixels are disposed in the display area according to the embodiment of the present disclosure.

FIG. 4 illustrates the arrangement of the subpixels SP in the three types of areas NA, DA1, and DA2 included in the display area DA of the display panel according to the embodiment of the present disclosure.

With reference to FIG. 4, the plurality of subpixels SP may be disposed in each of the normal area NA, the first optical area DA1, and the second optical area DA2 included in the display area.

For example, the plurality of subpixels SP may include a red subpixel Red SP configured to emit red light, a green subpixel Green SP configured to emit green light, and a blue subpixel Blue SP configured to emit blue light.

Therefore, the normal area NA, the first optical area DA1, and the second optical area DA2 may each include a light-emitting area EA for the red subpixel Red SP, a light-emitting area EA for the green subpixel Green SP, and a light-emitting area EA for the blue subpixel Blue SP.

FIG. 4 illustrates different directions of light-emitting areas EA of the plurality of green subpixels Green SP. However, the present disclosure is not limited thereto. For example, all the directions of the light-emitting areas EA of the plurality of green subpixels Green SP may be identical to one another.

With reference to FIG. 4, the normal area NA may include the light-emitting area EA without including the light transmission structure.

However, the first optical area DA1 and the second optical area DA2 may include the light transmission structure while including the light-emitting area EA.

Therefore, the first optical area DA1 may include the light-emitting area EA and a first transmissive area TA1, and the second optical area DA2 may include the light-emitting area EA and a second transmissive area TA2.

The light-emitting area EA and the transmissive areas TA1 and TA2 may be distinguished depending on a degree to which light may be transmitted. For example, the light-emitting area EA may be an area smaller in amount of transmitted light than the transmissive areas TA1 and TA2.

In addition, the light-emitting area EA and the transmissive areas TA1 and TA2 may be distinguished depending on whether a particular metal layer is formed. In addition, a light-blocking layer (in case that the light-blocking layer is a metal layer) may be formed in the light-emitting area EA, but no light-blocking layer may be formed in the transmissive areas TA1 and TA2.

The first optical area DA1 includes the first transmissive area TA1, and the second optical area DA2 includes the second transmissive area TA2, such that both the first optical area DA1 and the second optical area DA2 may transmit light.

The transmittance (degree of light transmission) of the first optical area DA1 and the transmittance (degree of light transmission) of the second optical area DA2 may be equal to each other.

In this case, the first transmissive area TA1 of the first optical area DA1 and the second transmissive area TA2 of the second optical area DA2 may be identical in shape or size. Alternatively, even though the first transmissive area TA1 of the first optical area DA1 and the second transmissive area TA2 of the second optical area DA2 are different in shape or size, a proportion of the first transmissive area TA1 in the first optical area DA1 and a proportion of the second transmissive area TA2 in the second optical area DA2 may be equal to each other.

Alternatively, the transmittance (degree of light transmission) of the first optical area DA1 and the transmittance (degree of light transmission) of the second optical area DA2 may be different from each other.

In this case, the first transmissive area TA1 of the first optical area DA1 and the second transmissive area TA2 of the second optical area DA2 may be different in shape or size. Alternatively, even though the first transmissive area TA1 of the first optical area DA1 and the second transmissive area TA2 of the second optical area DA2 are identical in shape or size, a proportion of the first transmissive area TA1 in the first optical area DA1 and a proportion of the second transmissive area TA2 in the second optical area DA2 may be different from each other.

For example, in case that the first electronic optical device, which overlaps the first optical area DA1, is a camera and the second electronic optical device, which overlaps the second optical area DA2, is a detection sensor, the camera may require a larger light amount than the detection sensor.

Therefore, the transmittance (degree of light transmission) of the first optical area DA1 may be higher than the transmittance (degree of light transmission) of the second optical area DA2.

In this case, the first transmissive area TA1 of the first optical area DA1 may have a larger size than the second transmissive area TA2 of the second optical area DA2. Alternatively, even though the first transmissive area TA1 of the first optical area DA1 and the second transmissive area TA2 of the second optical area DA2 are identical in size, a proportion of the first transmissive area TA1 in the first optical area DA1 may be larger than a proportion of the second transmissive area TA2 in the second optical area DA2.

Hereinafter, for convenience of description, an example will be described in which the transmittance (degree of light transmission) of the first optical area DA1 is higher than the transmittance (degree of light transmission) of the second optical area DA2.

In the embodiment of the present disclosure, the transmissive areas TA1 and TA2 illustrated in FIG. 4 may each be referred to as a transparent area, and the transmittance may be referred to as transparency.

In the embodiment of the present disclosure, as illustrated in FIG. 4, it is assumed that the first optical area DA1 and the second optical area DA2 are positioned at an upper end of the display area of the display panel and disposed side by side in a leftward/rightward direction.

With reference to FIG. 4, a horizontal display area, in which the first optical area DA1 and the second optical area DA2 are disposed, is referred to as a first horizontal display area HA1, and a horizontal display area, in which the first optical area DA1 and the second optical area DA2 are not disposed, is referred to as a second horizontal display area HA2.

The first horizontal display area HA1 may include the normal area NA, the first optical area DA1, and the second optical area DA2. In contrast, the second horizontal display area HA2 may include only the normal area NA.

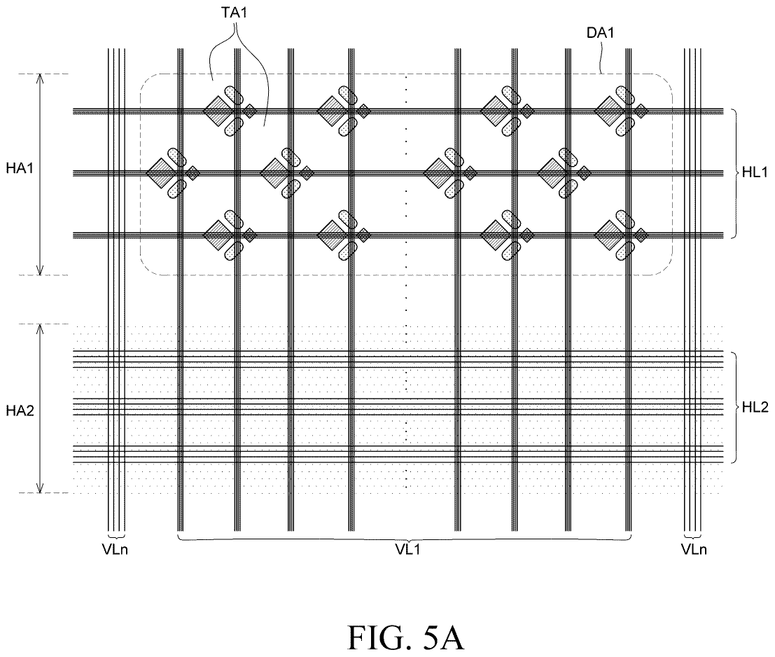

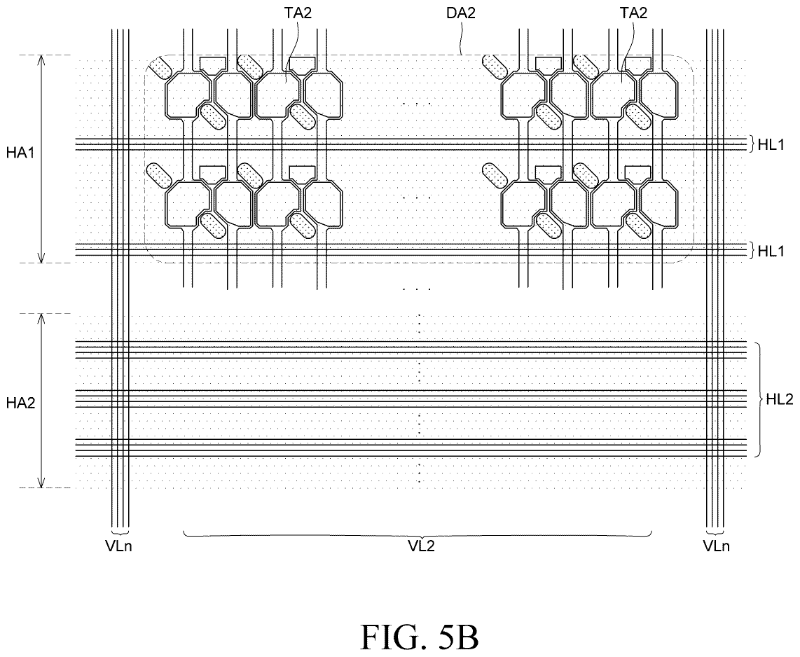

FIG. 5A is a view illustrating an example in which signal lines are disposed in the first optical area and the normal area according to the embodiment of the present disclosure.

FIG. 5B is a view illustrating an example in which the signal lines are disposed in the second optical area and the normal area according to the embodiment of the present disclosure.

FIG. 5A illustrates the arrangement of the signal lines in the first optical area DA1 and the normal area NA of the display panel DP according to the embodiment of the present disclosure. FIG. 5B illustrates the arrangement of the signal lines in the second optical area DA2 and the normal area NA of the display panel DP according to the embodiment of the present disclosure.

FIG. 5A illustrates a part of the first horizontal display area HA1 and a part of the first optical area DA1. FIG. 5B illustrates a part of the second horizontal display area HA2 and a part of the second optical area DA2. In addition, as illustrated in FIGS. 5A and 5B, the first horizontal display area HA1 may include the normal area, the first optical area DA1, and the second optical area DA2, and the second horizontal display area HA2 may include the normal area.

Various types of horizontal lines HL1 and HL2 and various types of vertical lines VLn, VL1, and VL2 may be disposed on the display panel DP.

In the embodiment of the present disclosure, a horizontal direction and a vertical direction may mean two directions intersecting each other. The horizontal direction and the vertical direction may be different from each other in a viewing direction. For example, in the embodiment of the present disclosure, the horizontal direction may mean a direction in which one gate line is disposed while extending, and the vertical direction may mean a direction in which one data line is disposed while extending.

With reference to FIGS. 5A and 5B, horizontal lines disposed on the display panel DP may include a first horizontal line HL1 disposed in the first horizontal display area HA1, and a second horizontal line HL2 disposed in the second horizontal display area HA2. In this case, the first horizontal line HL1 and the second horizontal line HL2 may each be the gate line. The gate line may include various types of gate lines in accordance with the structure of the subpixel.

With reference to FIGS. 5A and 5B, the vertical line disposed on the display panel DP may include a normal vertical line VLn disposed only in the normal area, a first vertical line VL1 configured to pass through both the first optical area DA1 and the normal area, and a second vertical line VL2 configured to pass through both the second optical area DA2 and the normal area.

With reference to FIGS. 4 and 5A, the first optical area DA1 included in the first horizontal area HA1 may include the light-emitting area EA and the first transmissive area TA1. In the first optical area DA1, an outer area of the first transmissive area TA1 may include the light-emitting area EA.

With reference to FIG. 5A, in order to improve the transmittance of the first optical area DA1, the first horizontal line HL1 passing through the first optical area DA1 may extend while bypassing the first transmissive area TA1 in the first optical area DA1. Therefore, the first horizontal line HL1 passing through the first optical area DA1 may include a curved section, a bending section, or the like that bypasses a portion disposed outside an outer peripheral rim of the first transmissive area TA1.

In addition, in order to improve the transmittance of the first optical area DA1, the first vertical line VL1 passing through the first optical area DA1 may extend while bypassing the first transmissive area TA1 in the first optical area DA1. Therefore, the first vertical line VL1 passing through the first optical area DA1 may include a curved section, a bending section, or the like that bypasses a portion disposed outside an outer peripheral rim of the first transmissive area TA1.

With reference to FIG. 5A, the light-emitting area may be disposed between the two first transmissive areas TA1, which are disposed adjacent to each other in the leftward/rightward direction, in the first optical area DA1 in the first horizontal area HA1. The light-emitting area may be disposed between the two first transmissive areas, which are disposed adjacent to each other in the upward/downward direction, in the first optical area DA1 in the first horizontal area HA1.

With reference to FIGS. 4 and 5B, the second optical area DA2 included in the first horizontal area HA1 may include the light-emitting area EA and the second transmissive area TA2. In the second optical area DA2, an outer area of the second transmissive area TA2 may include the light-emitting area EA.

As illustrated in FIG. 5B, the positions and arrangement states of the light-emitting area EA and the second transmissive area TA2 in the second optical area DA2 may be different from the positions and arrangement states of the light-emitting area EA and the first transmissive area TA1 in the first optical area DA1 in FIG. 5A.

However, the positions and arrangement states of the light-emitting area EA and the second transmissive area TA2 in the second optical area DA2 may be identical to the positions and arrangement states of the light-emitting area EA and the first transmissive area TA1 in the first optical area DA1 in FIG. 5A.

In addition, in order to improve the transmittance of the second optical area DA2, the second vertical line VL2 passing through the second optical area DA2 may extend while bypassing the second transmissive area TA2 in the second optical area DA2. As illustrated in FIG. 5B, the second vertical line VL2 passing through the second optical area DA2 may include a curved section, a bending section, or the like that bypasses a portion disposed outside an outer peripheral rim of the second transmissive area TA2. Therefore, the second vertical line VL2, which passes through the second optical area DA2, and the normal vertical line VLn, which is disposed in the normal area without passing through the second optical area DA2, may be different in shape or length.

The first optical area DA1, which at least partially overlaps the first electronic optical device 170a, includes the plurality of first transmissive areas TA1, and the second optical area DA2, which at least partially overlaps the second electronic optical device 170b, includes the plurality of second transmissive areas TA2. Therefore, the number of subpixels, to which the first horizontal line HL1 passing through the first optical area DA1 and the second optical area DA2 is connected, may be different from the number of subpixels to which the second horizontal line HL2, which is disposed only in the normal area NA without passing through the first optical area DA1 and the second optical area DA2, is connected.

That is, the first optical area DA1 and the second optical area DA2 may be smaller in number of subpixels per unit area than the normal area NA.

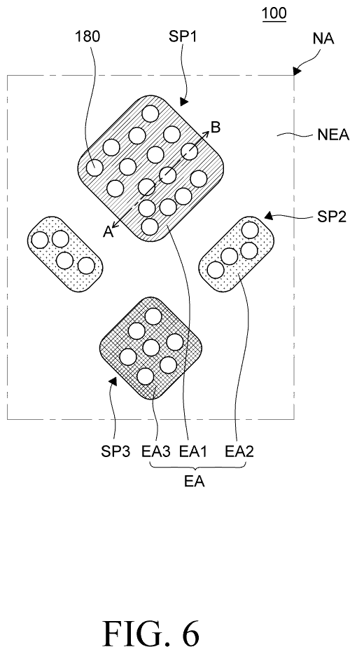

Hereinafter, planar structures of the normal area NA and the first optical area DA1 of the display device 100 according to the embodiment of the present disclosure will be described in detail with reference to FIG. 6.

FIG. 6 is a top plan view illustrating the normal area of the display device according to the embodiment of the present disclosure.

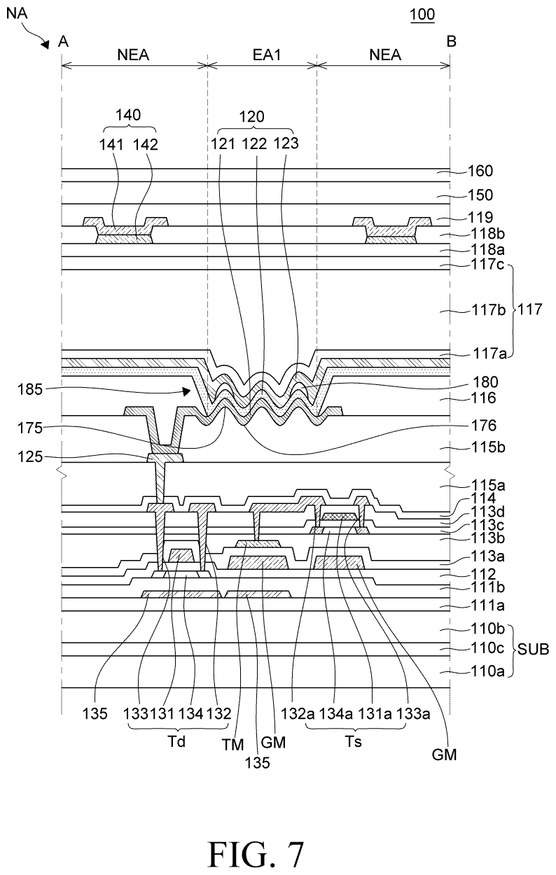

FIG. 7 is a cross-sectional view taken along line A-B in FIG. 6.

A first subpixel SP1 included in the normal area NA of the display device 100 will be described as an example with reference to FIG. 7. However, the description of the first subpixel SP1 may also be applied to a second subpixel SP2 and a third subpixel SP3 included in the normal area NA in the same way.

With reference to FIGS. 6 and 7, the display device 100 may include the normal area NA.

The normal area NA may include at least one light-emitting area EA, and a non-light-emitting area NEA configured to surround the light-emitting area EA.

The plurality of light-emitting areas EA may include a first light-emitting area EA1 of the first subpixel SP1, a second light-emitting area EA2 of the second subpixel SP2, and a third light-emitting area EA3 of the third subpixel SP3.

In this case, the first light-emitting area EA1 may be a blue (B) light-emitting area, the second light-emitting area EA2 may be a green (B) light-emitting area, and the third light-emitting area EA3 may be a red (R) light-emitting area. However, the present disclosure is not limited thereto.

The areas of the first light-emitting area EA1, the second light-emitting area EA2, and the third light-emitting area EA3 disposed in the normal area NA may be different from one another. However, the present disclosure is not limited thereto. For example, among the first light-emitting area EA1, the second light-emitting area EA2, and the third light-emitting area EA3, the areas of at least two light-emitting areas EA may be equal to each other.

In addition, the shapes of the first light-emitting area EA1, the second light-emitting area EA2, and the third light-emitting area EA3 disposed in the normal area NA may be different from one another. However, the present disclosure is not limited thereto. For example, among the first light-emitting area EA1, the second light-emitting area EA2, and the third light-emitting area EA3, the shapes of at least two light-emitting areas EA may be equal to each other.

A plurality of patterns 180 may be disposed in at least one light-emitting area EA among the first light-emitting area EA1, the second light-emitting area EA2, and the third light-emitting area EA3 disposed in the normal area NA.

The plurality of patterns 180 may be disposed to be spaced apart from one another.

In addition, the plurality of patterns 180 may be irregularly arranged in one light-emitting area EA.

A plurality of transistors Td and Ts, a first light-emitting element 120, an encapsulation layer (ENCAP) 117, and a plurality of touch electrodes 140 may be disposed on the substrate SUB in the normal area NA of the display device 100.

The substrate SUB is a component for supporting various constituent elements included in the organic light-emitting display device 100 and may be made of an insulating material. The substrate SUB may include a first substrate 110a, a second substrate 110b, and an interlayer insulation film 110c. The interlayer insulation film 110c may be disposed between the first substrate 110a and the second substrate 110b.

As described above, the substrate SUB may include the first substrate 110a, the second substrate 110b, and the interlayer insulation film 110c, which may suppress moisture permeation. For example, the first substrate 110a and the second substrate 110b may each be a substrate made of polyimide (PI).

Various types of patterns 131, 132, 133, 134, 131a, 132a, 133a, and 134a, various types of insulation films 111a, 111b, 112, 113a, 113b, and 114, and various types of metal patterns TM, GM, and 135 may be disposed on the substrate SUB in the normal area NA in order to form at least one capacitor and thin-film transistors such as the driving transistor Td and at least one switching transistor Ts.

Specifically, a multi-buffer layer 111a may be disposed on the second substrate 110b, and an active buffer layer 111b may be disposed on the multi-buffer layer 111a.

The multi-buffer layer 111a and the active buffer layer 111b may each be configured as a single layer made of silicon nitride (SiNx) or silicon oxide (SiOx) or a multilayer made of silicon nitride (SiNx) or silicon oxide (SiOx). However, the present disclosure is not limited thereto.

A metal layer 135 may be disposed on the multi-buffer layer 111a.

In this case, the metal layer 135 may serve as a light shield and be also referred to as a light-blocking layer. The metal layer 135 may be made of any one of molybdenum (Mo), aluminum (Al), chromium (Cr), gold (Au), titanium (Ti), nickel (Ni), neodymium (Nd), copper (Cu), and an alloy of two or more of these materials. Alternatively, the metal layer 135 may be configured as a multilayer made of any one of molybdenum (Mo), aluminum (Al), chromium (Cr), gold (Au), titanium (Ti), nickel (Ni), neodymium (Nd), copper (Cu), and an alloy of two or more of these materials. However, the present disclosure is not limited thereto.

The active buffer layer 111b may be disposed on the metal layer 135.

A first active layer 134 of the driving transistor Td may be disposed on the active buffer layer 111b. The first active layer 134 may be made of polycrystalline silicon (p-Si), amorphous silicon (a-Si), or an oxide semiconductor. However, the present disclosure is not limited thereto.

Meanwhile, the driving transistor Td may be formed on the active buffer layer 111b and include the first active layer 134, a first gate insulation film 112 configured to cover the first active layer 134, a first gate electrode 131 disposed on the first gate insulation film 112, a first interlayer insulation film 113a configured to cover the first gate electrode 131, a second gate insulation film 113b disposed on the first interlayer insulation film 113a, a third interlayer insulation film 113c disposed on the second gate insulation film 113b, a first source electrode 132 and a first drain electrode 133 disposed on the third interlayer insulation film 113c.

The first gate insulation film 112 may be disposed on the first active layer 134. The first gate insulation film 112 may be configured as a single layer made of silicon nitride (SiNx) or silicon oxide (SiOx) or a multilayer made of silicon nitride (SiNx) or silicon oxide (SiOx).

The first gate electrode 131 of the driving transistor Td may be disposed on the first gate insulation film 112. The first gate electrode 131 is disposed on the first gate insulation layer 112 and overlaps the first active layer 134.

The first gate electrode 131 may be made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A gate material layer GM may be disposed on the first gate insulation film 112 and provided at a position different from a position at which the driving transistor Td is formed.

The first interlayer insulation film 113a may be disposed on the first gate electrode 131 and the gate material layer GM.

The metal pattern TM may be disposed on the first interlayer insulation film 113a.

A second interlayer insulation film 113b may be disposed while covering the metal pattern TM disposed on the first interlayer insulation film 113a.

The second interlayer insulation film 113b may serve to space a second active layer 234 from the first active layer 134.

The second active layer 234 of the switching transistor Ts may be disposed on the second interlayer insulation film 113b. For example, the second active layer 234 may be made of polycrystalline silicon, amorphous silicon, or an oxide semiconductor. However, the present disclosure is not limited thereto.

A second gate insulation film 113c may be disposed on the second active layer 234.

In addition, a second gate electrode 231 of the switching transistor Ts may be disposed on the second gate insulation film 113c. The second gate electrode 231 is disposed on the second gate insulation film 113c and overlaps the second active layer 234.

The second gate insulation film 113c covers the second active layer 234 of the switching transistor Ts. Because the second gate insulation film 113c is formed on the second active layer 234, the second gate insulation film 113c may include an inorganic insulating material. For example, the second gate insulation film 113c may be configured as a single layer made of silicon nitride (SiNx) or silicon oxide (SiOx) or a multilayer made of silicon nitride (SiNx) or silicon oxide (SiOx).

The second gate electrode 231 may include a metallic material. For example, the second gate electrode 231 may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

Meanwhile, the switching transistor Ts may be formed on the second interlayer insulation film 113b and include the second active layer 234, the second gate insulation film 113c configured to cover the second active layer 234, the second gate electrode 231 disposed on the second gate insulation film 113c, the third interlayer insulation film 113c configured to cover the second gate electrode 231, and a second source electrode 232 and a second drain electrode 233 disposed on the third interlayer insulation film 113c.

The switching transistor Ts may further include the gate material layer GM positioned below the first interlayer insulation film 113a and configured to overlap the second active layer 234. The gate material layer GM may block light entering the second active layer 234, thereby ensuring the reliability of the switching transistor Ts.

The gate material layer GM may be made of the same material as the first gate electrode 131 and formed on a top surface of the first gate insulation film 112. The gate material layer GM may be electrically connected to the second gate electrode 234 and constitute a dual gate.

The first source electrode 132 and the first drain electrode 133 of the driving transistor Td and the second source electrode 232 and the second drain electrode 233 of the switching transistor Ts may be disposed on a third interlayer insulation film 113d.

The second source electrode 232 and the second drain electrode 233 may be formed on the third interlayer insulation film 113d and made of the same material as the first source electrode 132 and the first drain electrode 133, thereby reducing the number of mask processes.

The first source electrode 132 and the first drain electrode 133 may be respectively connected to one side and the other side of the first active layer 134 through contact holes provided in the third interlayer insulation film 113d, the second gate insulation film 113c, the second interlayer insulation film 113b, the first interlayer insulation film 113a, and the first gate insulation film 112.

The second source electrode 232 and the second drain electrode 233 may be respectively connected to one side and the other side of the second active layer 234 through contact holes provided in the third interlayer insulation film 113d and the second gate insulation film 113c.

The first source electrode 132, the first drain electrode 133, the second source electrode 232, and the second drain electrode 233 may each be configured as a single layer or multilayer made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A portion of the first active layer 134, which overlaps the first gate electrode 131, is a channel area. One of the first source electrode 132 and the first drain electrode 133 is connected to one side of the channel area on the first active layer 134, and the other of the first source electrode 132 and the first drain electrode 133 is connected to the other side of the channel area on the first active layer 134.

The second active layer 234 may be configured in the same shape as the first active layer 134. In case that the second active layer 234 is implemented by an oxide semiconductor material, the second active layer 234 includes a genuine second channel area, which is not doped with impurities, and a second source area and a second drain area that are doped with impurities and thus have conductivity.

A passivation layer 114 may be disposed on the first source electrode 132, the first drain electrode 133, the second source electrode 232, and the second drain electrode 233. The passivation layer 114 may serve to protect the driving transistor Td and include an inorganic insulating material. For example, the passivation layer 114 may be configured as a single layer made of silicon nitride (SiNx) or silicon oxide (SiOx) or a multilayer made of silicon nitride (SiNx) or silicon oxide (SiOx).

Meanwhile, the gate material layer GM and the metal pattern TM may be disposed on the first gate insulation film 112 while overlapping each other, thereby implementing the capacitor Cst.

The metal pattern TM may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The capacitor Cst stores the data voltage applied through the data line DL for a predetermined period of time and provides the data voltage to the first light-emitting element 120. The capacitor Cst may include two electrodes, which corresponds to each other, and a dielectric material between the two electrodes. The first interlayer insulation film 113a may be positioned between the gate material layer GM and the metal pattern TM.

The gate material layer GM or the metal pattern TM of the capacitor Cst may be electrically connected to the second source electrode 232 or the second drain electrode 233 of the switching transistor Ts. However, the present disclosure is not limited thereto. A connection relationship of the capacitor Cst may vary depending on the pixel drive circuit.

In addition, the metal layer 135 may be additionally disposed on the multi-buffer layer 111a to overlap the gate material layer GM and the metal pattern TM, thereby constituting the dual capacitor Cst.

In the embodiment of the present disclosure, the at least one switching transistor Ts has an active layer made of an oxide semiconductor.

The transistor having the active layer made of an oxide semiconductor provides an excellent effect of blocking a leakage current and requires a relatively low manufacturing cost in comparison with a transistor having an active layer made of polycrystalline silicon. Therefore, the pixel circuit according to the embodiment of the present disclosure includes a driving transistor or at least one switching transistor made of an oxide semiconductor material in order to reduce power consumption and manufacturing costs.

All the transistors, which include the driving transistor and constitute the pixel circuit, may each have the active layer made of an oxide semiconductor. Alternatively, only some transistors may be implemented by using an oxide semiconductor.

However, the transistor implemented by using an oxide semiconductor hardly ensures the reliability. The transistor implemented by using polycrystalline silicon may provide a high operating speed and excellent reliability. Therefore, the embodiment of the present disclosure includes both the transistor implemented by using an oxide semiconductor and the transistor implemented by using polycrystalline silicon.

However, the present disclosure is not limited thereto. Only the transistor implemented by using an oxide semiconductor or only the transistor implemented by using polycrystalline silicon may be applied to constitute the pixel circuit in accordance with design.

A planarization layer may be disposed on the driving transistor Td, protect the driving transistor Td, and planarize an upper portion of the driving transistor Td.

The planarization layer may include a first planarization layer 115a and a second planarization layer 115b. The first planarization layer 115a may be disposed on the passivation layer 114, and a connection electrode 125 may be disposed on the first planarization layer 115a.

The connection electrode 125 may be connected to one of the first source electrode 132 and the first drain electrode 133 through a contact hole provided in the first planarization layer 115a.

The second planarization layer 115b may be disposed on the connection electrode 125.

The first light-emitting element 120 may be positioned above the second planarization layer 115b.

The connection electrode 125 may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The first planarization layer 115a and the second planarization layer 115b may each include an organic insulating material. For example, the first planarization layer 115a and the second planarization layer 115b may each be made of any one of acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto.

A plurality of convex areas 175 and a plurality of concave areas 176 may be provided in a part of a top surface of the second planarization layer 115b.

The plurality of convex areas 175 may be implemented convexly from the top surface of the second planarization layer 115b.

The plurality of concave areas 176 may be implemented concavely from the top surface of the second planarization layer 115b. Alternatively, the plurality of concave areas 176 may refer to areas lower in positions of the top surfaces than the plurality of convex areas 175.

In the following description, the convex area refers to an area convex from the top surface of the second planarization layer 115b regardless of the reference numeral.

In addition, the concave area refers to an area concave from the top surface of the second planarization layer 115b or refers to an area lower in the position of the top surface than the convex area. This configuration may mean that the position of the top surface is lowered as a distance between the top surface of the corresponding component and the top surface of the substrate SUB decreases. For example, this configuration means that a distance between a bottom surface of the concave area and the substrate SUB is shorter than a distance between a convex surface of the convex area and the substrate SUB.

The plurality of convex areas 175 and the plurality of concave areas 176 may have the same depth based on the top surface of the second planarization layer 115b. However, the present disclosure is not limited thereto. For example, the depth of each of the plurality of convex areas 175 and the depth of each of the plurality of concave areas 176 may be different from each other.

In addition, the plurality of convex areas 175 and the plurality of concave areas 176 may be provided on the second planarization layer 115b, which overlaps the first light-emitting area EA1, so that the plurality of convex areas 175 and the plurality of concave areas 176 have shapes capable of maximizing the efficiency in extracting light, which is emitted from the first subpixel SP1, to the outside based on the effective light-emitting area of the first light-emitting element 120.

The plurality of convex areas 175 of the second planarization layer 115b and the plurality of concave areas 176 of the second planarization layer 115b may change a propagation route of the light, which is emitted from the first organic layer 122 of the first light-emitting element 120, toward a light emergent surface and emit the light, which is totally reflected in the first light-emitting element 120, toward the light emergent surface, thereby suppressing or minimizing a deterioration in light extraction efficiency caused by the light trapped in the first light-emitting element 120. Therefore, the display device 100 may operate with low power consumption in terms of a reduction in power consumption.

The first electrode 121 (or a first-first electrode) of the first light-emitting element 120 may be disposed on the second planarization layer 115b. In this case, the first electrode 121 may be electrically connected to the connection electrode 125 through a contact hole provided in the second planarization layer 115b.

The first electrode 121 may include a metallic material.

In case that the display device 100 according to the embodiment of the present disclosure is a top-emission type display device in which light emitted from the first light-emitting element 120 propagates toward a position above the substrate SUB, the first electrode 121 may further include a transparent conductive layer, and a reflective layer disposed on the transparent conductive layer.

For example, the transparent conductive layer may be made of transparent conductive oxide such as indium tin oxide (ITO), indium zinc oxide (IZO), or indium gallium zinc oxide (IGZO). For example, the reflective layer may be made of silver (Ag), aluminum (Al), gold (Au), molybdenum (Mo), tungsten (W), chromium (Cr), or an alloy thereof.

The first electrode 121 may be disposed to overlap the plurality of convex areas 175 and the plurality of concave areas 176 disposed on the top surface of the second planarization layer 115b.

In an area in which the first electrode 121 overlaps the plurality of convex areas 175 and the plurality of concave areas 176, the first electrode 121 may be formed along surface shapes (morphology) of the plurality of convex areas 175 and the plurality of concave areas 176 in an intact manner.

Therefore, in the area in which the first electrode 121 overlaps the plurality of convex areas 175 and the plurality of concave areas 176, the first electrode 121 may include the plurality of convex areas and the plurality of concave areas.

A bank 116 may be disposed on the first electrode 121 and the second planarization layer 115b.

The bank 116 may be disposed on an edge of the first electrode 121 and the second planarization layer 115b.

The bank 116 may not be disposed in an area corresponding to the first light-emitting area EA1 of the first subpixel SP1. In another aspect, a hole 185 of the bank 116 may be disposed in the first light-emitting area EA1 of the first subpixel SP1.

The hole 185 of the bank 116 may overlap a part of the first electrode 121. That is, a part of the first electrode 121 may not overlap the bank 116.

In this case, the bank 116 may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

The hole 185 of the bank 116 may at least partially overlap the plurality of convex areas 175 and the plurality of concave areas 176 of the second planarization layer 115b.

In addition, the hole 185 of the bank 116 may at least partially overlap the plurality of convex areas and the plurality of concave areas included in the first electrode 121.

The first organic layer 122 of the first light-emitting element 120 may be disposed in the hole 185 of the bank 116 and disposed around the hole 185 of the bank 116. Therefore, the first organic layer 122 may be disposed on the first electrode 121 exposed through the hole 185 of the bank 116.

The first organic layer 122 may include a light-emitting layer and further include at least one function layer, among a hole transport layer, a hole injection layer, an electron transport layer, and an electron injection layer, in addition to the light-emitting layer that emits light with a particular color. The first organic layer 122 may include a plurality of organic films.

The first organic layer 122 may overlap the plurality of convex areas 175 and the plurality of concave areas 176 of the second planarization layer 115b in the hole 185 of the bank 116.

In addition, the first organic layer 122 may overlap the plurality of convex areas and the plurality of concave areas included in the first electrode 121 in the hole 185 of the bank 116.

The first organic layer 122 may be formed along a surface shape of the first electrode 121 in the hole 185 of the bank 116. Therefore, the first organic layer 122 may include a plurality of convex areas and a plurality of concave areas.

The first organic layer 122 may have a predetermined thickness in the hole 185 of the bank 116. However, the structure of the first organic layer 122 of the display device 100 according to the embodiment of the present disclosure is not limited thereto.

For example, the first organic layer 122 may have a thickness that gradually increases toward an area corresponding to a bottom surface of the convex area 175 or the concave area 176, and the first organic layer 122 may have a smallest thickness in an area corresponding to an inclined surface between the convex area 175 and the concave area 176.

The plurality of patterns 180 may be disposed on the first organic layer 122.

The second electrode 123 of the first light-emitting element 120 may be disposed on the plurality of patterns 180 and the first organic layer 122.

The plurality of patterns 180 may be disposed in the hole 185 of the bank 116. The plurality of patterns 180 may be disposed to be spaced apart from one another.

The plurality of patterns 180 may include beads. For example, the plurality of patterns 180 may include silica beads or conductive beads. However, the present disclosure is not limited thereto.

The plurality of patterns 180 may be formed on the first organic layer 122, and the second electrode 123 may be formed to cover surfaces of the plurality of patterns 180. However, the present disclosure is not limited thereto.

For example, the plurality of patterns 180 may be formed by a process of forming the second electrode 123. A raw material, which is made by mixing a material of the second electrode 123 and the plurality of patterns 180 may be deposited on the first organic layer 122. In this case, a part of the top surface of at least one of the plurality of patterns 180 may be exposed by the second electrode 123. However, the present disclosure is not limited thereto.

The plurality of patterns 180 may be disposed in the hole 185 of the bank 116 and expose a part of the top surface of the first organic layer 122.

For example, the plurality of patterns 180 may be disposed to expose some of the plurality of convex areas of the first organic layer 122 and expose some of the plurality of concave areas of the first organic layer 122.

In addition, FIG. 7 illustrates the structure in which the plurality of patterns 180 are each disposed in the area corresponding to the convex area 175 of the second planarization layer 115b. However, the positions of the plurality of patterns 180 are not limited thereto.

For example, some of the plurality of patterns 180 may be disposed in the area corresponding to the convex area 175 of the second planarization layer 115b, and some of the remaining patterns 180 may be disposed in the area corresponding to the concave area 176 of the second planarization layer 115b.

Alternatively, the plurality of patterns 180 may each be disposed in the area corresponding to the concave area 176 of the second planarization layer 115b.

The second electrode 123 may include a transparent electrically conductive material such as indium tin oxide (ITO) and indium zinc oxide (IZO) or include a metal alloy such as MgAg or an ytterbium (Yb) alloy. The second electrode 123 may further include a metal doping layer. However, the present disclosure is not limited thereto.

The second electrode 123 may be formed along surface shapes of the plurality of patterns 180 and the first organic layer 122 in the hole 185 of the bank 116.

Therefore, the second electrode 123 may include a portion where the top surface is not flat in the hole 185 of the bank 116.

In addition, there may be two or more portions where the position of the top surface of the second electrode 123 varies in the hole 185 of the bank 116.

Specifically, in the hole 185 of the bank 116, the second electrode 123 may include a portion disposed on the pattern 180 disposed on the first organic layer 122 and the first organic layer 122, and a portion disposed only on the first organic layer 122. A position of the top surface of the second electrode 123 on the portion where the second electrode 123 is disposed on the pattern 180 disposed on the first organic layer 122 and the first organic layer 122 may be higher than a position of the top surface of the second electrode 123 on the portion where the second electrode 123 is disposed only on the first organic layer 122.

In addition, the second electrode 123 may include a plurality of convex areas and a plurality of concave areas. With the plurality of patterns 180, heights of at least two convex areas of the second electrode 123 may be different from each other, and depths of at least two concave areas of the second electrode 123 may be different from each other.

The first electrode 121, the first organic layer 122, and the second electrode 123 of the first light-emitting element 120 may each have the structure in which a top surface of the light-emitting area EA is not flat.

Therefore, a route of the light generated by the first organic layer 122 of the first light-emitting element 120 may be changed by the plurality of convex areas 175 and the plurality of concave areas 176, such that the light extraction efficiency may be improved. Therefore, the high efficiency and high luminance may be implemented, such that the lifespan of the light-emitting layer may be increased. Further, the power consumption may be reduced, such that the low power consumption may be implemented.

The encapsulation layer 117 may be disposed on the second electrode 123.

The encapsulation layer 117 may have a single-layer structure or a multilayer structure. For example, the encapsulation layer 117 may include a first encapsulation layer 117a, a second encapsulation layer 117b, and a third encapsulation layer 117c.

The first encapsulation layer 117a and the third encapsulation layer 117c may each be made of an inorganic film, and the second encapsulation layer 117b may be made of an organic film. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the second electrode 123 and disposed to be closest to the first light-emitting element 120.

The first encapsulation layer 117a may be formed along a surface shape of the second electrode 123. Therefore, a surface of the first encapsulation layer 117a may not be flat in the hole 185 of the bank 116.

The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the first organic layer 122 of the first light-emitting element 120 made of an organic material vulnerable to a high-temperature ambience during a deposition process.

The second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present disclosure is not limited thereto.

In addition, although not illustrated, a structure for blocking a flow of the second encapsulation layer 117b, which constitutes the encapsulation layer 117, may be disposed in the non-display area NDA. In order to inhibit the encapsulation layer 117 from being collapsed, one or more structures may be disposed at an end point of an inclined surface of the encapsulation layer 117 or disposed at a position adjacent to the inclined surface of the encapsulation layer 117.

The one or more structures may be disposed at a boundary point between the display area DA and the non-display area NDA or disposed at a position adjacent to the boundary point. The structure may include one or more layers at least made of an organic material. For example, the structure may include a lower layer disposed on the same layer and made of the same material as the second planarization layer 115b, and an upper layer disposed on the same layer and made of the same material as the bank 116. However, the present disclosure is not limited thereto.

The third encapsulation layer 117c may be formed above the substrate SUB having the second encapsulation layer 117b to cover a top surface and a side surface of each of the second encapsulation layer 117b and the first encapsulation layer 117a.

In this case, the third encapsulation layer 117c may minimize or block the permeation of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

A touch buffer film 118a may be disposed on the encapsulation layer 117, and a touch electrode 140 may be disposed on the touch buffer film 118a.

The touch electrode 140 may include a touch sensor electrode 141 and a bridge electrode 142 positioned on different layers. A touch interlayer insulation film 118b may be disposed between the touch sensor electrode 141 and the bridge electrode 142.

For example, the touch sensor electrode 141 may include a first touch sensor electrode, a second touch sensor electrode, and a third touch sensor electrode disposed adjacent to one another.

For example, the first touch sensor electrode and the second touch sensor electrode may be arranged in a first direction, and the third touch sensor electrode may be arranged in a second direction intersecting the first touch sensor electrode and the second touch sensor electrode.

The first touch sensor electrode and the second touch sensor electrode may be electrically connected to each other. However, in case that there is the third touch sensor electrode arranged in the second direction intersecting the first direction between the first touch sensor electrode and the second touch sensor electrode arranged in the first direction, the first touch sensor electrode and the second touch sensor electrode may be electrically connected through the bridge electrode 142 disposed on another layer.

The bridge electrode 142 may be insulated from the third touch sensor electrode by the touch interlayer insulation film 118b.

In other words, in order to inhibit the plurality of touch electrodes, which are arranged in the first direction and the second direction, from being short-circuited in the area in which the plurality of touch electrodes intersect one another, the plurality of touch electrodes extending in the first direction may be electrically connected through the bridge electrode 142.

During the process of forming the touch electrode 140, a liquid chemical (a developer, an etching liquid, or the like) used for the process may be produced, or moisture or the like may be produced from the outside.

Therefore, the touch electrode 140 is disposed on the touch buffer film 118a, such that it is possible to inhibit a liquid chemical, moisture, or the like from permeating into the first organic layer 122 of the first light-emitting element 120 including an organic material during the process of forming the touch electrode 140, thereby suppressing damage to the first organic layer 122.

In order to suppress damage to the first organic layer 122 of the first light-emitting element 120 including an organic material vulnerable to a high temperature, the touch buffer film 118a may be made of an organic insulating material that may be formed at a predetermined low temperature (e.g., 100° C. or less) and have low permittivity of 1 to 3. For example, the touch buffer film 118a may be made of an acrylic-based, epoxy-based, or siloxane-based material.

A protective layer 119 may be disposed to cover the plurality of touch electrodes 140, a touch routing line, and a ground line. The protective layer 119 may be made of an organic insulation film.

An organic material layer 150 may be disposed to cover the protective layer 119.

In case that only the protective layer 119 made of an organic insulation film is disposed on an uppermost layer of the display device 100, only the protective layer 119 cannot perfectly compensate for a level difference caused by the touch electrode 140 disposed below the protective layer 119, which may cause a problem in that the user visually recognizes a Mura caused by the plurality of touch electrodes 140. Therefore, the organic material layer 150 made of an organic insulation film is additionally disposed on the upper portion of the protective layer 119, which may improve the visibility by suppressing a level difference on the uppermost layer of the display device 100.

The organic material layer 150 may be made of the same material as the second sealing layer 117b of the sealing layer 117. For example, the organic material layer 150 may be made of an organic insulating material such as acrylic resin, epoxy resin, polyimide, polyethylene, or silicon oxycarbon (SiOC). The organic material layer 150 may also be formed in an inkjet manner. However, the present disclosure is not limited thereto.

As described above, in the display device 100 according to the embodiment of the present disclosure, a first anti-deposition layer 170 is disposed in the entire normal area NA, and a third sub-electrode of the second electrode 123 is not disposed, which may suppress an increase in thickness of the second electrode 123 in the normal area NA.

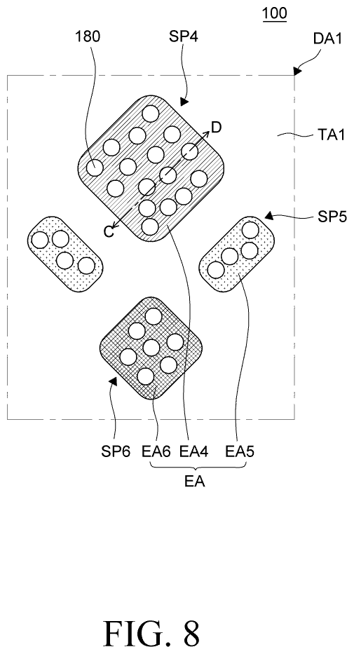

FIG. 8 is a top plan view schematically illustrating the first optical area of the display device according to the embodiment of the present disclosure.

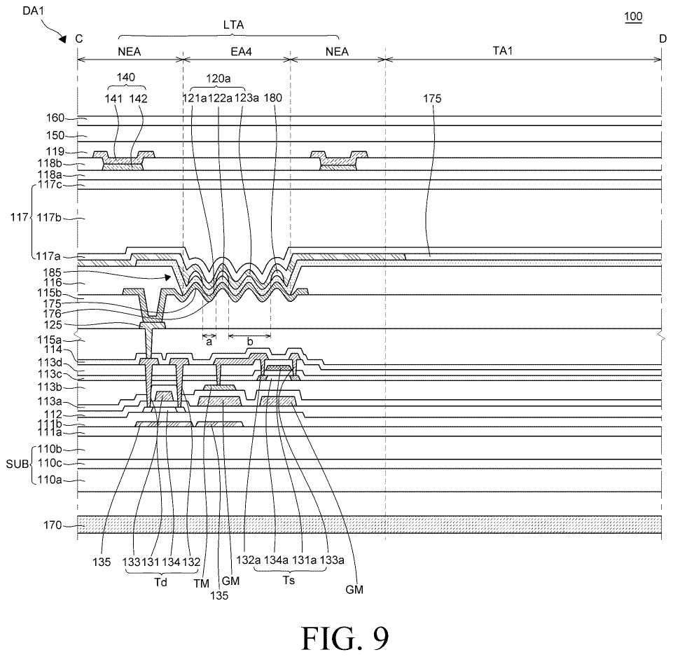

FIG. 9 is a cross-sectional view taken along line C-D in FIG. 8.

Hereinafter, for convenience of description, an example will be described in which the display area DA of the display device 100 includes the normal area NA and the first optical area DA1 (i.e., FIGS. 1A and 1B). However, the description of the first optical area DA1 may also be equally applied to the second optical area DA2.

In addition, a first subpixel SP4 included in the first optical area DA1 of the display device 100 will be described as an example with reference to FIG. 9. However, the description of the fourth subpixel SP4 included in the first optical area DA1 may also be applied to a fifth subpixel SP5 and a sixth subpixel SP6 included in the first optical area DA1 in the same way.

With reference to FIGS. 8 and 9, the first optical area DA1 may include the plurality of light-emitting areas EA and the first transmissive area TA1.

The plurality of light-emitting areas EA disposed in the first optical area DA1 may include a fourth light-emitting area EA4 of the fourth subpixel SP4, a fifth light-emitting area EA5 of the fifth subpixel SP5, and a sixth light-emitting area EA6 of the sixth subpixel SP6.

In this case, the fourth light-emitting area EA4 may be a blue (B) light-emitting area, the fifth light-emitting area EA5 may be a green (B) light-emitting area, and the sixth light-emitting area EA6 may be a red (R) light-emitting area. However, the present disclosure is not limited thereto.

The areas of the fourth light-emitting area EA4, the fifth light-emitting area EA5, and the sixth light-emitting area EA6 disposed in the first optical area DA1 may be different from one another. However, the present disclosure is not limited thereto. For example, among the fourth light-emitting area EA4, the fifth light-emitting area EA5, and the sixth light-emitting area EA6, the areas of at least two light-emitting areas EA may be equal to each other.

In addition, the shapes of the fourth light-emitting area EA4, the fifth light-emitting area EA5, and the sixth light-emitting area EA6 disposed in the first optical area DA1 may be different from one another. However, the present disclosure is not limited thereto. For example, among the fourth light-emitting area EA4, the fifth light-emitting area EA5, and the sixth light-emitting area EA6, the shapes of at least two light-emitting areas EA may be equal to each other.

A density of the light-emitting areas EA disposed in the first optical area DA1 may be lower than a density of the light-emitting areas EA disposed in the normal area NA. Therefore, it is possible to improve a transmittance rate of the first optical area DA1 in which the electronic optical device 170 is disposed.

The plurality of patterns 180 may be disposed in at least one light-emitting area EA among the fourth light-emitting area EA4, the fifth light-emitting area EA5, and the sixth light-emitting area EA6.

The plurality of patterns 180 may be disposed to be spaced apart from one another.

In addition, the plurality of patterns 180 may be irregularly arranged in one light-emitting area EA.

In addition, the plurality of patterns 180 may each have a circular shape in a plan view. However, the present disclosure is not limited thereto. The plurality of patterns 180 may have various shapes such as a semicircular shape, an elliptical shape, a semi-elliptical shape, and a polygonal shape in a plan view.

The first optical area DA1 may include the first transmissive area TA1 that surrounds the fourth light-emitting area EA4, the fifth light-emitting area EA5, and the sixth light-emitting area EA6.

The first optical area DA1 includes the first transmissive area TA1, which may improve the performance of the electronic device 170 disposed in the first optical area DA1.

The plurality of light-emitting areas EA of the first optical area DA1 may be included in a low transmission area LTA of the first optical area DA1.

In the first optical area DA1, a plurality of second light-emitting elements 120a for the plurality of light-emitting areas EA may be disposed in the low transmission area LTA, except for the first transmissive area TA1.

In addition, a plurality of pixel circuits for operating the plurality of second light-emitting elements 120a may be disposed in the low transmission area LTA. That is, the plurality of pixel circuits may be disposed in an optical area OA. The plurality of pixel circuits may include the driving transistor Td and the switching transistor Ts.

The low transmission area LTA of the first optical area DA1 may include a part of the non-light-emitting area NEA. The non-light-emitting area NEA disposed in the low transmission area LTA may include an area in which the plurality of pixel circuits is disposed. However, the present disclosure is not limited thereto.

For example, the plurality of pixel circuits may not be disposed in a first optical area OA1, and the plurality of pixel circuits may be disposed in an additional bezel area that surrounds an outer periphery of the first optical area OA1.

In the first optical area DA1, a transmittance rate of the low transmission area LTA is lower than a transmittance rate of the first transmissive area TA1. However, the transmittance rate of the low transmission area LTA in the first optical area DA1 may be higher than a transmittance rate of the normal area NA.

The low transmission area LTA of the first optical area DA1 in FIG. 9 is substantially identical in configuration to the normal area NA illustrated in FIG. 7, only except for positions of the plurality of patterns 180. Therefore, repeated descriptions of the identical components will be omitted.

The second light-emitting element 120a disposed in the first optical area DA1 may include a third electrode 121a (or a first electrode of the second light-emitting element), a second organic layer 122a, and a fourth electrode 123a (or a second electrode of the second light-emitting element).

The third electrode 121a of the second light-emitting element 120a may be an anode electrode, and the fourth electrode 123a of the second light-emitting element 120a may be a cathode electrode. However, the present disclosure is not limited thereto.

The plurality of patterns 180 may be disposed between the second organic layer 122a and the fourth electrode 123a in the hole 185 of the bank 116.

In the first optical area DA1, the plurality of patterns 180 may be disposed to expose a part of a top surface of the second organic layer 122a.

For example, the plurality of patterns 180 may be disposed to expose some of a plurality of convex areas of the second organic layer 122a and expose some of a plurality of concave areas of the second organic layer 122a.

In addition, FIG. 9 illustrates the structure in which the plurality of patterns 180 are each disposed in the area corresponding to the convex area 175 of the second planarization layer 115b. However, the positions of the plurality of patterns 180 are not limited thereto.

For example, some of the plurality of patterns 180 may be disposed in the area corresponding to the convex area 175 of the second planarization layer 115b, and some of the remaining patterns 180 may be disposed in the area corresponding to the concave area 176 of the second planarization layer 115b.

Alternatively, the plurality of patterns 180 may each be disposed in the area corresponding to the concave area 176 of the second planarization layer 115b.

The fourth electrode 123a may include a plurality of convex areas and a plurality of concave areas. With the plurality of patterns 180, heights of at least two convex areas of the fourth electrode 123a may be different from each other, and depths of at least two concave areas of the fourth electrode 123a may be different from each other.

In the first optical area DA1, distances between the plurality of patterns 180 may be randomly determined.

Specifically, a first distance a between one pattern 180 and another adjacent pattern 180 may be different from a second distance b between another pattern 180 and another adjacent pattern 180.

As described above, the plurality of convex areas 175 and the plurality of concave areas 176 are disposed on a top surface of the second planarization layer 112b in the low transmission area LTA of the first optical area DA1, which may improve the efficiency of the second light-emitting element 120a disposed on the second planarization layer 112b.

The plurality of convex areas 175 of the second planarization layer 115b and the plurality of concave areas 176 of the second planarization layer 115b may change a propagation route of the light, which is emitted from the second organic layer 122a of the second light-emitting element 120a, toward a light emergent surface and emit the light, which is totally reflected in the second light-emitting element 120a, toward the light emergent surface, thereby suppressing or minimizing a deterioration in light extraction efficiency caused by the light trapped in the second light-emitting element 120a.

In addition, the plurality of patterns 180 are disposed to overlap the plurality of convex areas 175 of the second planarization layer 112b and the plurality of concave areas 176 of the second planarization layer 112b, such that it is possible to additionally emit light, which cannot be emitted to the outside of the display device 100, only by forming the plurality of convex areas 175 of the second planarization layer 115b and the plurality of concave areas 176 of the second planarization layer 115b.

Specifically, because of the plurality of patterns 180, the surface shape of the fourth electrode 123a of the second light-emitting element 120a may become non-flat and more irregular. Because the surface shape of the fourth electrode 123a becomes irregular, the light beams, which are not changed in routes only by the plurality of convex areas 175 of the second planarization layer 112b and the plurality of concave areas 176 of the second planarization layer 112b among the light beams totally reflected in the second light-emitting element 120a, may be additionally emitted toward the light emergent surface. Therefore, the light extraction efficiency of the display device 100 may be further improved, and the display device 100 may operate with low power consumption in terms of a reduction in power consumption.

The substrate SUB and the various types of insulation films 111a, 111b, 112, 113a, 113b, 114, 115a, 115b, 117a, 117b, 117c, 118a, 118b, and 119 disposed in the low transmission area LTA of the first optical area DA1 may also be disposed in a transmissive area TA of the first optical area DA1 in the same way in the first transmissive area TA1 of the first optical area DA1.

In addition, an organic material layer 190 and a polarizing layer 160 may be additionally disposed in the first transmissive area TA1 of the first optical area DA1. However, the present disclosure is not limited thereto.

Meanwhile, FIG. 9 illustrates a structure in which the bank 116 is disposed to extend to the first transmissive area TA1. However, the present disclosure is not limited thereto. For example, the bank 116 may not be disposed in the first transmissive area TA1. Alternatively, the bank 116 may be disposed only in a partial area of the first transmissive area TA1.

Other than the insulating material disposed in the low transmission area LTA of the first optical area DA1, a material layer having electrical or opaque properties may not be disposed in the first transmissive area TA1 of the first optical area DA1.

For example, the metallic material layers 131, 132, 133, 135, GM, TM, 131a, 132a, and 133a and the active layers 134 and 134a related to the transistor may not be disposed in the first transmissive area TA1.

In addition, the touch electrode 140 may be disposed in the low transmission area LTA, whereas the touch electrode 140 may not be disposed in the first transmissive area TA1. In addition, the touch electrode 140 may be disposed in the non-light-emitting area NEA included in the low transmission area LTA.

In addition, the first electrode 121 included in the light-emitting element 120 may not be disposed in the first transmissive area TA1.

Because the first transmissive area TA1 of the first optical area DA1 overlaps the electronic device 190, the opaque constituent elements, such as the metal electrode, are not disposed in the first transmissive area TA1 for a normal operation of the electronic device 190, which may increase the transmittance rate of the first transmissive area TA1.

In addition, because the constituent element, such as the metal electrode, is not disposed in the first transmissive area TA1 of the first optical area DA1, the top surface of the first transmissive area TA1 of the first optical area DA1 may be configured only by flat layers.

The second organic layer 122a included in the second light-emitting element 120a may be disposed in the first transmissive area TA1. However, the present disclosure is not limited thereto.

For example, the second organic layer 122a included in the second light-emitting element 120a may not be disposed in the first transmissive area TA1 or may be disposed only in a partial area of the first transmissive area TA1.

In addition, in case that the second organic layer 122a is configured as a plurality of layers, some of the layers may be disposed to extend to the first transmissive area TA1. For example, the light-emitting layer included in the second organic layer 122a may not be disposed in the first transmissive area TA1.

The fourth electrode 123a of the second light-emitting element 120a may be disposed only in a partial area of the first transmissive area TA1.

At least one anti-deposition layer 175 may be disposed in the first transmissive area TA1.

The anti-deposition layer 175 may include a non-metallic material. For example, the anti-deposition layer 175 may include an organic material.

The anti-deposition layer 175 may serve to inhibit the fourth electrode 123a from being formed during the process of forming the fourth electrode 123a of the second light-emitting element 120a. In other words, the fourth electrode 123a of the second light-emitting element 120a may not be formed in the area in which the anti-deposition layer 175 is disposed.

In case that the fourth electrode 123a of the second light-emitting element 120a is disposed in the entire first transmissive area TA1, there may occur a problem in that the transmittance rate of the first transmissive area TA1 decreases.

However, in the display device 100 according to the embodiment of the present disclosure, at least one anti-deposition layer 175 is disposed in a partial area of the first transmissive area TA1, such that the fourth electrode 123a of the second light-emitting element 120a is inhibited from being disposed in the entire first transmissive area TA1, which may increase the transmittance rate of the first transmissive area TA1 and improve the performance of the electronic device 190.

As described above, in the display device 100 according to the embodiment of the present disclosure, the plurality of convex areas 175 of the second planarization layer 115b and the plurality of concave areas 176 of the second planarization layer 115b may change a propagation route of the light, which is emitted from the second organic layer 122a of the second light-emitting element 120a, toward a light emergent surface and emit the light, which is totally reflected in the second light-emitting element 120a, toward the light emergent surface, thereby suppressing or minimizing a deterioration in light extraction efficiency caused by the light trapped in the second light-emitting element 120a.

In addition, the plurality of patterns 180 are disposed to overlap the plurality of convex areas 175 of the second planarization layer 112b and the plurality of concave areas 176 of the second planarization layer 112b, such that it is possible to additionally emit light, which cannot be emitted to the outside of the display device 100, only by forming the plurality of convex areas 175 of the second planarization layer 115b and the plurality of concave areas 176 of the second planarization layer 115b.

Therefore, the efficiency of the second light-emitting element 120a disposed in the first optical area DA1 may be improved, a degradation may be suppressed, and the lifespan of the second light-emitting element 120a may be improved.

FIGS. 8 and 9 illustrate the structure in which the second planarization layer 115b includes the plurality of convex areas 175 and the plurality of concave areas 176 in the light-emitting area EA. However, the structure of the display device of the present disclosure is not limited thereto.

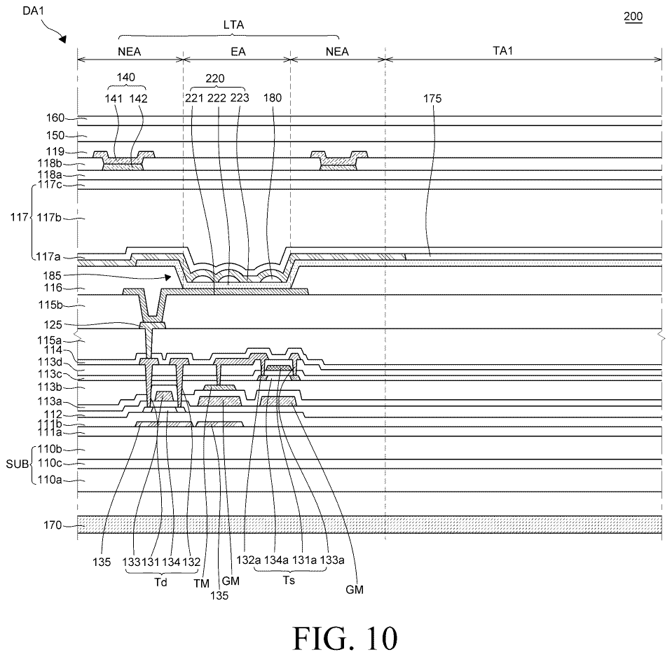

FIG. 10 is a cross-sectional view illustrating a first optical area of a display device according to another embodiment of the present disclosure.

A display device 200 in FIG. 10 is substantially identical in configuration to the display device 100 in FIG. 9, except that the top surface of the second planarization layer 115b in the light-emitting area EA of the first optical area DA1 is flat, and top surfaces of a third electrode 221 and a second organic layer 222 of a second light-emitting element 220 disposed on the second planarization layer 115b are flat. Therefore, repeated descriptions of the identical components will be omitted.

With reference to FIG. 10, a top surface of the second planarization layer 115b disposed below the third electrode 221 of a second light-emitting element 200 may be flat in the remaining area excluding the contact hole of the first optical area DA1.

Therefore, the top surfaces of the third electrode 221 and the second organic layer 222 of the second light-emitting element 200 disposed on the second planarization layer 115b in the light-emitting area EA of the first optical area DA1 may be flat.

The plurality of patterns 180 may be disposed between the second organic layer 222 and a fourth electrode 223 in the light-emitting area EA of the first optical area DA1.

The plurality of patterns 180 may be disposed to expose a part of the top surface of the second organic layer 222.

The fourth electrode 223 of the second light-emitting element 220 may be disposed on the second organic layer 222 and the plurality of patterns 180 in the light-emitting area EA of the first optical area DA1. The fourth electrode 223 may be formed along surface shapes of the plurality of patterns 180 and a surface shape of the second organic layer 222 in an intact manner.

Therefore, the surface of the fourth electrode 223 of the second light-emitting element 220 is not flat along the surface shapes of the plurality of patterns 180 in the area in which the plurality of patterns 180 are disposed. For example, the fourth electrode 223 may include at least one concave area and at least one convex area in a part of the light-emitting area EA.

In addition, the surface may be flat along the surface shape of the second organic layer 222 in the area in which the plurality of patterns 180 are not disposed and the surface adjoins the top surface of the second organic layer 222.

The first encapsulation layer 117a disposed on the fourth electrode 223 of the second light-emitting element 220 may be formed along the surface shape of the fourth electrode 223 in an intact manner.

Therefore, the surface of the first encapsulation layer 117a may include a flat area and a non-flat area in the light-emitting area EA of the first optical area DA1.

As described above, because the plurality of patterns 180 are disposed in at least a part of the light-emitting area EA of the first optical area DA1, the fourth electrode 223 of the second light-emitting element 220 includes at least one concave area and at least one convex area, such that the route of the light generated by the second organic layer 222 may be changed by the concave area and the convex area of the fourth electrode 223. In particular, the concave area and the convex area of the fourth electrode 223 serve to allow the light to propagate to the outside of the display device 200 by changing the route of the light that is trapped in the display device 200 without propagating to the outside, such that the light extraction efficiency of the display device 200, particularly, the light extraction efficiency of the first optical area DA1 may be improved.

A luminance difference between the first optical area DA1 and the normal area NA may be compensated because the light extraction efficiency of the first optical area DA1 is improved even though a density of the light-emitting areas EA of the first optical area DA1 is lower than a density of the light-emitting areas EA of the normal area NA. In addition, the display device 200 may operate with low power consumption in terms of a reduction in power consumption.

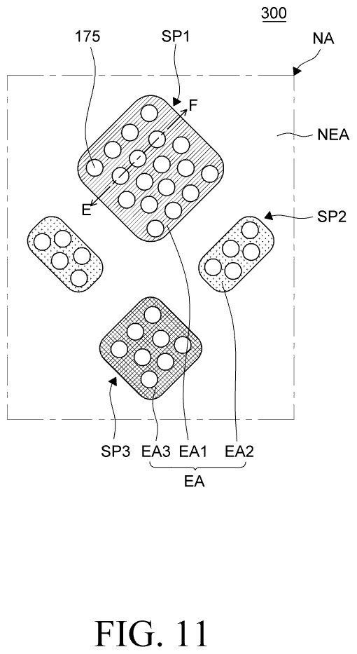

FIG. 11 is a top plan view illustrating a normal area of a display device according to still another embodiment of the present disclosure.

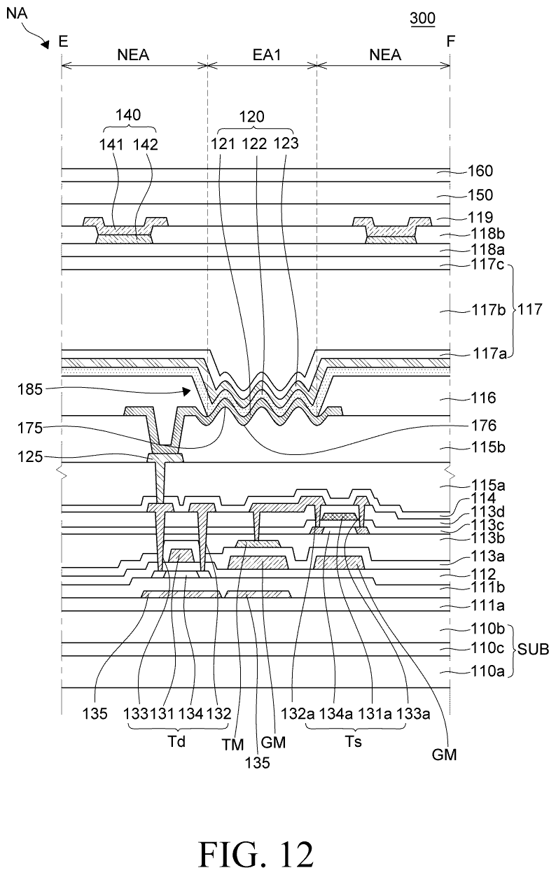

FIG. 12 is a cross-sectional view taken along line C-D in FIG. 11.

A display device 300 in FIGS. 11 and 12 is substantially identical in configuration to the display device 100 in FIGS. 6 and 7, except that the plurality of patterns 180 are not disposed. Therefore, repeated descriptions of the identical components will be omitted.

With reference to FIGS. 11 and 12, the display device 300 may include the plurality of light-emitting areas EA.

The plurality of convex areas 175 may be disposed in at least one light-emitting area EA among the plurality of light-emitting areas EA.

Specifically, the plurality of convex areas 175 and the plurality of concave areas 176 may be provided in a part of the top surface of the second planarization layer 115b. One convex area 175 may be connected to at least one concave area 176.

The first electrode 121 of the first light-emitting element 120 may be disposed on the second planarization layer 115b.

The first electrode 121 may be disposed to overlap the plurality of convex areas 175 and the plurality of concave areas 176 disposed on the top surface of the second planarization layer 115b.

In the area in which the first electrode 121 overlaps the plurality of convex areas 175 and the plurality of concave areas 176, the first electrode 121 may include the plurality of convex areas and the plurality of concave areas.

The bank 116, which exposes the top surface of the first electrode 121 in the first light-emitting area EA1, may be disposed on the first electrode 121 and the second planarization layer 115b.

The first organic layer 122 of the first light-emitting element 120 may be disposed in the hole 185 of the bank 116 and disposed around the hole 185 of the bank 116.

The first organic layer 122 may include the plurality of convex areas and the plurality of concave areas that respectively overlap the plurality of convex areas 175 and the plurality of concave areas 176 disposed on the top surface of the second planarization layer 115b in the first light-emitting area EA1.

The second electrode 123 of the first light-emitting element 120 may be disposed on the first organic layer 122.

The second electrode 123 may include the plurality of convex areas and the plurality of concave areas that respectively overlap the plurality of convex areas 175 and the plurality of concave areas 176 disposed on the top surface of the second planarization layer 115b in the first light-emitting area EA1.

That is, in the first light-emitting area EA1 disposed in the normal area NA of the display device 300, the first electrode 121, the first organic layer 122, and the second electrode 123 may each include the plurality of convex areas and the plurality of concave areas that respectively overlap the plurality of convex areas 175 and the plurality of concave areas 176 disposed on the top surface of the second planarization layer 115b.

The plurality of convex areas 175 and the plurality of concave areas 176 disposed on the top surface of the second planarization layer 115b may be arranged regularly. However, the present disclosure is not limited thereto.

The plurality of convex areas 175 of the second planarization layer 115b and the plurality of concave areas 176 of the second planarization layer 115b may change a propagation route of the light, which is emitted from the first organic layer 122 of the first light-emitting element 120, toward a light emergent surface and emit the light, which is totally reflected in the first light-emitting element 120, toward the light emergent surface, thereby suppressing or minimizing a deterioration in light extraction efficiency caused by the light trapped in the first light-emitting element 120.

In addition, the display device 300 may operate with low power consumption in terms of a reduction in power consumption.

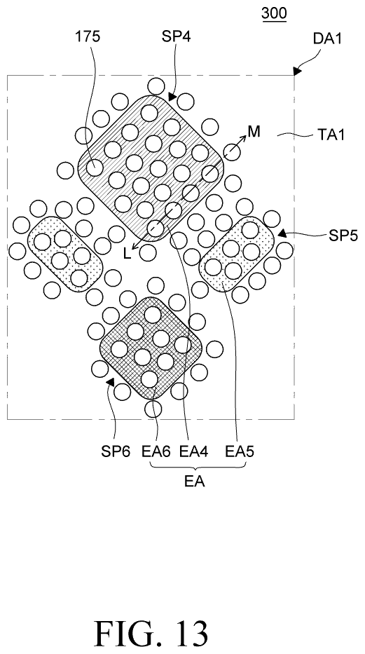

FIG. 13 is a top plan view schematically illustrating a first optical area of a display device according to yet another embodiment of the present disclosure.

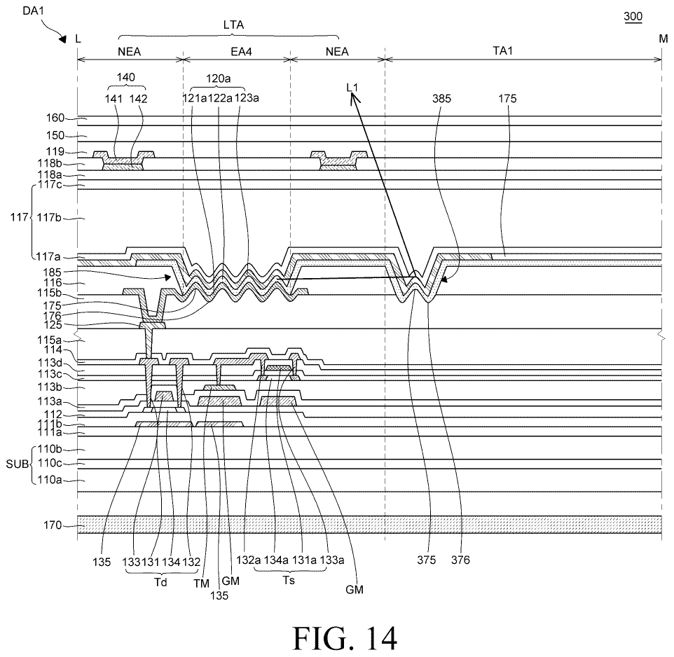

FIG. 14 is a cross-sectional view taken along line L-M in FIG. 13.

The structure of the first optical area DA1 in FIGS. 13 and 14 is substantially identical in configuration to the structure of the normal area NA in FIGS. 11 and 12, except that the first transmissive area TA1 is further included. Therefore, repeated descriptions of the identical components will be omitted.

With reference to FIGS. 13 and 14, the first optical area DA1 of the display device 300 includes the fourth light-emitting area EA4, the fifth light-emitting area EA5, and the sixth light-emitting area EA6 respectively included in the fourth subpixel SP4, the fifth subpixel SP5, and the sixth subpixel SP6.

The display device 300 may include at least one convex area 175 and at least one concave area 176 disposed in at least one light-emitting area EA among the fourth light-emitting area EA4, the fifth light-emitting area EA5, and the sixth light-emitting area EA6.

In addition, at least one additional convex area 375 or at least one additional concave area 376 may be disposed in an area adjacent to at least one light-emitting area EA disposed in the first optical area DA1.

In case that a plurality of additional convex areas 375 and a plurality of additional concave areas 376 are disposed in the first optical area DA1, the plurality of additional convex areas 375 and the plurality of additional concave areas 376 may be disposed to surround a periphery of at least one light-emitting area EA.

Meanwhile, FIGS. 13 and 14 illustrate the structure in which the additional convex area 375 and the additional concave area 376 are disposed in the first transmissive area TA1. However, the present disclosure is not limited thereto.

The additional convex area 375 and the additional concave area 376 may each be disposed in the non-light-emitting area NEA disposed in the low transmission area LTA of the first optical area DA1. That is, the additional convex area 375 and the additional concave area 376 may each be disposed in the remaining area excluding the light-emitting area EA in the first optical area DA1.

Specifically, at least one additional convex area 375 and at least one additional concave area 376 may be disposed on a part of the top surface of the second planarization layer 115b.

The additional convex area 375 and the additional concave area 376 may each be disposed in an additional hole 385 of the bank 116.

The additional hole 385 of the bank 116 may be disposed to surround at least a part of a periphery of at least one light-emitting area EA disposed in the first optical area DA1.

The second organic layer 122a of the second light-emitting element 120a may be disposed in the additional convex area 375 and the additional concave area 376.

The second organic layer 122a may be formed along the surface shapes of the additional convex area 375 and the additional concave area 376 of the second planarization layer 115b in an intact manner.

Therefore, the second organic layer 122a may have a convex shape in the area in which the additional convex area 375 of the second planarization layer 115b is disposed, and the second organic layer 122a may have a concave shape in the area in which the additional concave area 376 is disposed.

The fourth electrode 123a of the second light-emitting element 120a may be disposed on the second organic layer 122a disposed in the additional convex area 375 and the additional concave area 376.

The fourth electrode 123a may be formed along the surface shape of the second organic layer 122a in an intact manner.

Therefore, the fourth electrode 123a may have a convex shape in the area in which the additional convex area 375 of the second planarization layer 115b is disposed, and the fourth electrode 123a may have a concave shape in the area in which the additional concave area 376 is disposed.

In addition, at least one of the encapsulation layer 117 disposed on the fourth electrode 123a may have a convex shape in the area in which the additional convex area 375 of the second planarization layer 115b is disposed, and at least one of the encapsulation layer 117 may have a concave shape in the area in which the additional concave area 376 is disposed. For example, the first encapsulation layer 117a may have a convex shape in the area in which the additional convex area 375 of the second planarization layer 115b is disposed, and the first encapsulation layer 117a may have a concave shape in the area in which the additional concave area 376 is disposed.

As described above, the additional convex area 375 and the additional concave area 376 are disposed on the top surface of the second planarization layer 115b at the periphery of the light-emitting area EA disposed in the first optical area DA1, and the second organic layer 122a, the fourth electrode 123a, and the first encapsulation layer 117a disposed in the additional convex area 375 and the additional concave area 376 of the second planarization layer 115b each have the structure in accordance with the shape of the additional convex area 375 and the additional concave area 376 of the second planarization layer 115b, such that a route of a part of light L1 emitted from the second light-emitting element 120a disposed in the first light-emitting area EA1 of the low transmission area LTA may be changed, and the light may propagate to the outside of the display device 300.

Specifically, the light beams, which pass through the bank 160 and propagate to the first transmissive area TA1 among the light beams emitted from the second light-emitting element 120a, may be trapped in the display device 300 without propagating to the outside of the display device 300.

However, the additional convex area 375 and the additional concave area 376 are disposed on the top surface of the second planarization layer 115b at the periphery of the first light-emitting area EA1 disposed in the first optical area DA1 of the display device 300, and the second organic layer 122a, the fourth electrode 123a, and the first encapsulation layer 117a are formed in the additional convex area 375 and the additional concave area 376 along the shapes of the additional convex area 375 and the additional concave area 376, such that the route of the light L1, which passes through the bank 160 and propagates to the first transmissive area TA1 among the light beams emitted from the second light-emitting element 120a, may be changed, and the light may propagate to the outside of the display device 300.

Therefore, as illustrated in FIG. 14, with the additional convex area 375 and the additional concave area 376, at least a part of the light L1 propagating to the outside of the display device 300 may propagate from the non-light-emitting area NEA at the periphery of the fourth light-emitting area EA4 of the low transmission area LTA.

Therefore, with the additional convex area 375 and the additional concave area 376, the luminance of the non-light-emitting area NEA from which the light L1, which propagates to the outside of the display device 300, propagates may be higher than the luminance of the non-light-emitting area NEA disposed in the normal area NA of the display device 300.

In addition, with the additional convex area 375 and the additional concave area 376, the luminance of the non-light-emitting area NEA from which the light L1, which propagates to the outside of the display device 300, propagates may be lower than the luminance of the first light-emitting area EA1 disposed in the low transmission area LTA.

As described above, with the additional convex area 375 and the additional concave area 376, the light may propagate from at least a part of the non-light-emitting area NEA by the light L1 propagating to the outside of the display device 300, which may improve the light extraction efficiency of the first optical area DA1.

In addition, the display device 300 may operate with low power consumption in terms of a reduction in power consumption.

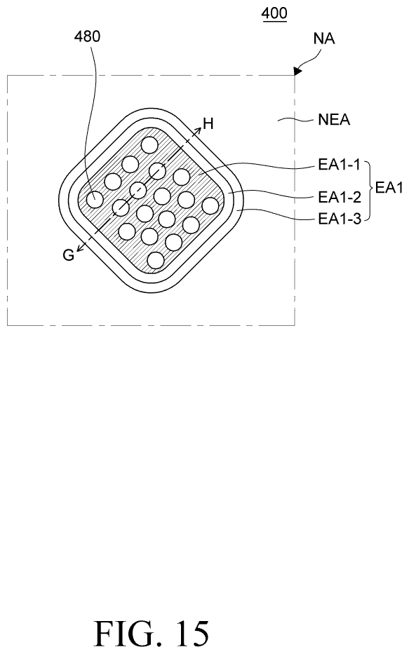

FIG. 15 is a top plan view illustrating a normal area of a display device according to still yet another embodiment of the present disclosure.

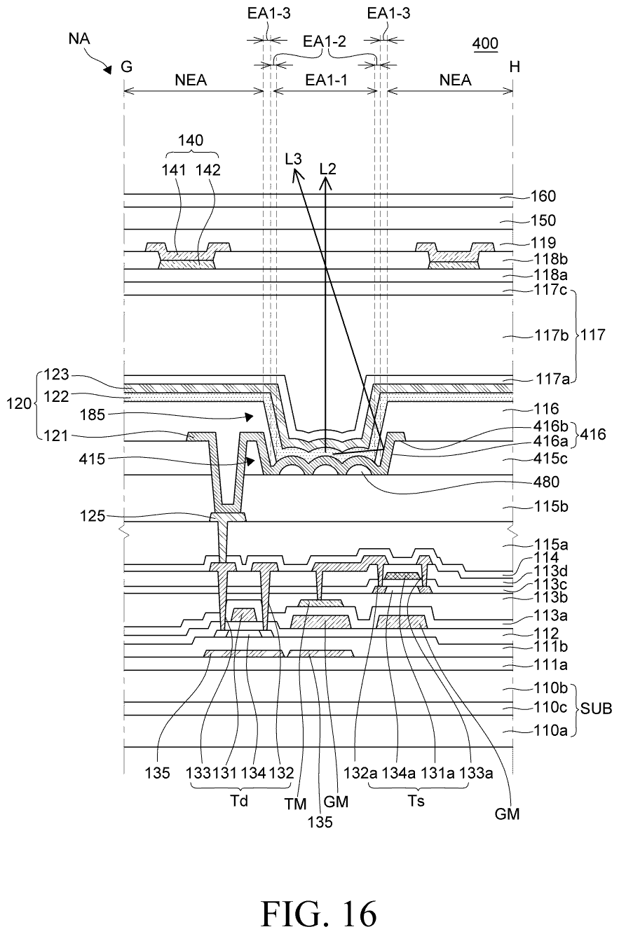

FIG. 16 is a cross-sectional view taken along line G-H in FIG. 15.

A display device 400 in FIGS. 15 and 16 is substantially identical in configuration to the display device 100 in FIGS. 6 and 7, except that a third planarization layer 415c is further disposed, and a plurality of protrusions 480 is disposed between the second planarization layer 115b and the first electrode 121. Therefore, repeated descriptions of the identical components will be omitted.

With reference to FIGS. 15 and 16, the plurality of protrusions 480 may be disposed in at least one light-emitting area EA among the plurality of light-emitting areas EA disposed in the normal area NA of the display device 400.

In this case, the plurality of protrusions 480 may be referred to as a plurality of convex areas. In addition, an area in which the plurality of protrusions 480 are not disposed may be referred to as a concave area.

The plurality of protrusions 480 may be disposed to be spaced apart from one another.

The plurality of protrusions 480 may be disposed at equal intervals. However, the present disclosure is not limited thereto. For example, the plurality of protrusions 480 may include irregularly arranged areas.

The plurality of protrusions 480 may be disposed on the second planarization layer 115b.

The plurality of protrusions 480 may each have a semicircular shape in a cross-sectional view. However, the present disclosure is not limited thereto. For example, the cross-sectional shape of each of the plurality of protrusions 480 may be a semi-elliptical shape, or a polygonal shape. In addition, the plurality of protrusions 480 may have the same shape, or at least two of the plurality of protrusions 480 may have different shapes.

The plurality of protrusions 480 and the third planarization layer 415c may be disposed on the second planarization layer 115b.

The third planarization layer 415c may include a protruding portion 416 and a concave portion 415.

The concave portion 415 of the third planarization layer 415c may expose a part of the top surface of the second planarization layer 112.

The concave portion 415 of the third planarization layer 415c may be disposed in an area corresponding to the first light-emitting area EA1 and the second light-emitting area EA2.

The protruding portion 416 of the third planarization layer 415c may include an inclined portion 416a, and a flat portion 416b extending from the inclined portion 416a.

The plurality of protrusions 480 may be disposed in the concave portion 415 of the third planarization layer 415c.

The plurality of protrusions 480 may be formed by forming the concave portion 415 and the protruding portion 416 on the third planarization layer 415c, forming an organic material layer for forming the plurality of protrusions 480, and then performing a patterning process.

Meanwhile, FIG. 16 illustrates the structure in which the plurality of protrusions 480 are disposed on the second planarization layer 115b in the concave portion 415 of the third planarization layer 415c. However, the present disclosure is not limited thereto. For example, a plurality of convex areas and a plurality of concave areas may be provided on the top surface of the second planarization layer 115b in the concave portion 415 of the third planarization layer 415c.

The first electrode 121 of the first light-emitting element 120 may be disposed in the concave portion 415 of the third planarization layer 415c and disposed in a partial area of the protruding portion 416. Specifically, first electrode 114 may be disposed in the concave portion 415, disposed on the inclined portion 416a of the protruding portion 416, and disposed in a partial area of the flat portion 416b.

The first electrode 121 may include a reflective electrode capable of reflecting light.

The first electrode 121 may also be disposed in contact holes provided in the second planarization layer 112 and the third planarization layer 415c.

The first electrode 121 may be in contact with a relay electrode 116 disposed below the second planarization layer 112 through the contact holes provided in the second planarization layer 112 and the third planarization layer 415c.

In the area corresponding to the concave portion 415 of the third planarization layer 415c, the first electrode 121 may be in contact with a part of the top surface of the second planarization layer 112 and the top surfaces of the plurality of protrusions 480.

The first electrode 121 may be formed along the surface shapes of the plurality of protrusions 480 disposed in the concave portion 415 of the third planarization layer 415c in an intact manner.

The area in which the first electrode 121 overlaps the plurality of protrusions 480 may be a convex area of the first electrode 121, and the area in which the first electrode 121 does not overlap the plurality of protrusions 480 may be a concave area of the first electrode 121.

The bank 116, which exposes the top surface of the first electrode 121 in the first light-emitting area EA1, may be disposed on the first electrode 121 and the third planarization layer 415c.

The bank 116 may include the hole 185 of the bank 116 that exposes a part of the top surface of the first electrode 121. That is, the hole 185 of the bank 116 may overlap a part of one first electrode 121.

The bank 116 may overlap a part of the concave portion 415 of the third planarization layer 415c. Specifically, the bank 116 may be disposed on a side surface of the third planarization layer 415c in the concave portion 415 of the third planarization layer 415c and also be disposed on a part of a top surface of a first electrode 311.

The bank 116 may also overlap a contact hole area. Specifically, the bank 116 may fill contact hole areas formed in the second planarization layer 115b and the third planarization layer 415c.

The first organic layer 122 of the first light-emitting element 120 may be disposed on the first electrode 121 and the bank 116. The first organic layer 122 may also be disposed in a concave portion 145 of the third planarization layer 415c.

The second electrode 123 of the first light-emitting element 120 may be disposed on the first organic layer 122. The second electrode 123 may also be disposed in the concave portion 145 of the third planarization layer 415c.

The first organic layer 122 and the second electrode 123 may be formed along the shape of the top surface of the first electrode 121 in an intact manner in the concave portion 145 of the third planarization layer 415c.

Therefore, the areas in which the first organic layer 122 and the second electrode 123 overlap the plurality of protrusions 480 may be convex areas of the first organic layer 122 and the second electrode 123, and the areas in which the first organic layer 122 and the second electrode 123 do not overlap the plurality of protrusions 480 may be concave areas of the first organic layer 122 and the second electrode 123.

In addition, the first encapsulation layer 117c disposed on the second electrode 123 may be formed along the shape of the top surface of the second electrode 123 in an intact manner in the concave portion 145 of the planarization layer 415c.

Therefore, the area in which the first encapsulation layer 117c overlaps the plurality of protrusions 480 may be a convex area of the first encapsulation layer 117c, and the area in which the first encapsulation layer 117c does not overlap the plurality of protrusions 480 may be a concave area of the first encapsulation layer 117c.

Meanwhile, among the plurality of light-emitting areas EA disposed in the normal area NA, at least one light-emitting area EA may include a plurality of sub-light-emitting areas.

For example, the first light-emitting area EA1 of the first subpixel SP1 disposed in the normal area NA may include a first sub-light-emitting area EA1-1, a second sub-light-emitting area EA1-2 configured to surround the first sub-light-emitting area EA1-1, and a third sub-light-emitting area EA1-3 configured to surround the second sub-light-emitting area EA1-2.

The luminance of the second sub-light-emitting area EA1-2 may be lower than the luminance of the first sub-light-emitting area EA1-1 and the luminance of the third sub-light-emitting area EA1-3. The luminance of the third sub-light-emitting area EA1-3 may be lower than the luminance of the first sub-light-emitting area EA1-1.

The first sub-light-emitting area EA1-1 may be an area in which the bank 116 is not disposed on the first electrode 121. That is, the area in which the hole 185 of the bank 116, which exposes a part of the top surface of the first electrode 121, is positioned in the concave portion 415 of the third planarization layer 415c may be the first sub-light-emitting area EA1-1.

The second sub-light-emitting area EA1-2 may include an area in which the concave portion 415 of the third planarization layer 415c and the bank 116 overlap each other.

The third sub-light-emitting area EA1-3 may include an area corresponding to the inclined portion 416a of the protruding portion 416 of the third planarization layer 415c. Alternatively, the third sub-light-emitting area EA1-3 may include an area in which the first electrode 121 is disposed on the inclined portion 416a.

The first electrode 121, the first organic layer 122, and the second electrode 123 of the first light-emitting element 120 may be disposed in the entire first sub-light-emitting area EA1-1, the entire second sub-light-emitting area EA1-2, and the entire third sub-light-emitting area EA1-3 and disposed in a part of the non-light-emitting area NEA.

In this case, the first sub-light-emitting area EA1-1 may be an area in which the light emitted from the first organic layer 122 of the first light-emitting element 120 passes through the second electrode 123 and propagates to the outside of the display device 400 or the light emitted from the first organic layer 122 is reflected by the first electrode 121 disposed in the first sub-light-emitting area EA1-1 and propagates to the outside of the display device 400.

The second sub-light-emitting area EA1-2 and the third sub-light-emitting area EA1-3 may each be an area in which the light emitted from the first organic layer 122 is reflected by the first electrode 121 disposed on the inclined portion 416a of the third planarization layer 415c and propagates to the outside of the display device 400.

Among the plurality of light-emitting areas EA disposed in the normal area NA, at least one light-emitting area EA includes the plurality of sub-light-emitting areas, such that the area of the light-emitting area may be increased, and the luminance properties of the normal area NA may be improved.

The plurality of protrusions 480 may be disposed in the first sub-light-emitting area EA1-1. Therefore, the luminance of the first sub-light-emitting area EA1-1 may be further improved.

Specifically, a part of light L2 emitted from the first light-emitting element 120 may propagate from the first organic layer 122 in the direction of the second electrode 123 and propagate to the outside of the display device 400.

In addition, another part of light L3 emitted from the first light-emitting element 120 may pass through the bank 116 disposed on the concave portion 415 of the third planarization layer 415b and reach the first electrode 121. Another part of light L3 emitted from the first light-emitting element 120 may be reflected by the first electrode 121 including the reflective electrode and propagate to the outside of the display device 400. Therefore, the light extraction efficiency of the display device 400 may be improved.

In addition, the display device 400 may operate with low power consumption in terms of a reduction in power consumption.

In addition, the first electrode 121, the first organic layer 122, and the second electrode 123 of the first light-emitting element 120 each include the plurality of convex areas and the plurality of concave areas in the concave portion 415 of the third planarization layer 415c, which may increase the amount of a part of the light that is emitted from the first light-emitting element 120 while changing in route, passes through the bank 116 disposed in the concave portion 415 of the third planarization layer 415b, and reaches the first electrode 121. Therefore, it is possible to reduce the amount of loss of the light emitted from the first light-emitting element 120 and increase the amount of light extracted to the outside of the display device 400.

In addition, it is possible to improve the efficiency of the first light-emitting element 120, suppress a degradation, and improve the lifespan of the first light-emitting element 120.

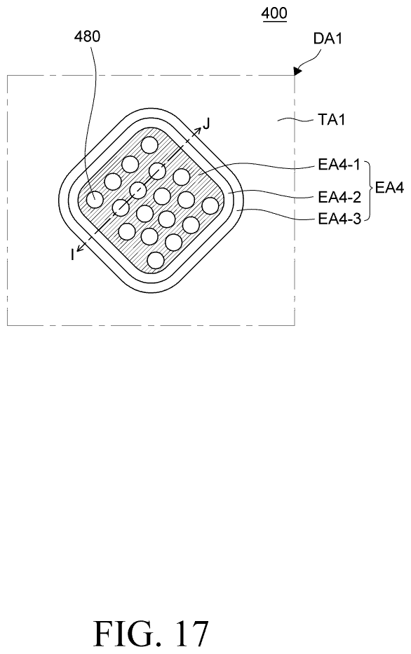

FIG. 17 is a top plan view schematically illustrating a first optical area of a display device according to a further embodiment of the present disclosure.

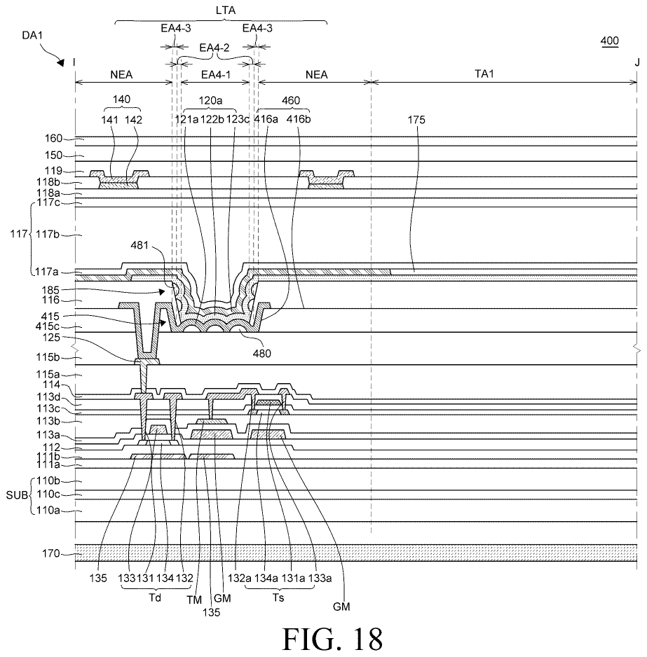

FIG. 18 is a cross-sectional view taken along line E-F in FIG. 17.

The structure of the first optical area DA1 in FIGS. 17 and 18 is substantially identical in configuration to the structure of the normal area NA in FIGS. 15 and 16, except that the first transmissive area TA1 is further provided, and an additional protrusion layer 481 is disposed in the light-emitting area. Therefore, repeated descriptions of the identical components will be omitted.

With reference to FIGS. 17 and 18, among the plurality of light-emitting areas EA disposed in the first optical area DA1 of the display device 400, at least one light-emitting area EA may include a plurality of sub-light-emitting areas.

For example, the fourth light-emitting area EA4 of the fourth subpixel SP4 disposed in the first optical area DA1 may include a first sub-light-emitting area EA4-1, a second sub-light-emitting area EA4-2 configured to surround the first sub-light-emitting area EA4-1, and a third sub-light-emitting area EA4-3 configured to surround the second sub-light-emitting area EA4-2.

The third electrode 121a, the second organic layer 122a, and the fourth electrode 123a of the second light-emitting element 120a may be disposed in the entire first sub-light-emitting area EA4-1, the entire second sub-light-emitting area EA4-2, and the entire third sub-light-emitting area EA4-3 of the low transmission area LTA and disposed in a part of the non-light-emitting area NEA of the low transmission area LTA.

In this case, the light propagating from the first sub-light-emitting area EA4-1 may include the light, which is emitted from the second organic layer 122a of the second light-emitting element 120a, passes through the fourth electrode 123a, and propagates to the outside of the display device 400, and the light that is emitted from the second organic layer 122a, is reflected by the third electrode 121a disposed in the first sub-light-emitting area EA4-1, and propagates to the outside of the display device 400. However, the present disclosure is not limited thereto.

The light propagating from the second sub-light-emitting area EA4-2 and the third sub-light-emitting area EA4-3 may include the light that is emitted from the second organic layer 122a, is reflected by the third electrode 121a disposed on the inclined portion 416a of the third planarization layer 415c, and propagates to the outside of the display device 400.

Among the plurality of light-emitting areas EA disposed in the first optical area DA1, at least one light-emitting area EA includes the plurality of sub-light-emitting areas, such that the area of the light-emitting area may be increased, and the luminance properties of the first optical area DA1 may be improved.

The plurality of protrusions 480 may be disposed in the first sub-light-emitting area EA4-1 of the first optical area DA1. The plurality of protrusions 480 may be disposed to be spaced apart from one another and disposed on the second planarization layer 115b.

In addition, the additional protrusion layer 481 may be disposed in at least a part of each of the second sub-light-emitting area EA4-2 and the third sub-light-emitting area EA4-3 of the first optical area DA1. However, the present disclosure is not limited thereto. The additional protrusion layer 481 may also overlap a part of the first sub-light-emitting area EA4-1 of the first optical area DA1.

Specifically, the additional protrusion layer 481 may be disposed on an inclined surface of the bank 116.

The additional protrusion layer 481 may be formed by forming an organic material layer or an inorganic material layer on the substrate SUB having the bank 116 and performing a patterning process using a halftone mask.

The additional protrusion layer 481 may be a layer including a plurality of protrusions disposed on the side surface of the bank 116. However, the present disclosure is not limited thereto. For example, the additional protrusion layer 481 may be a structure in which a plurality of protrusions is disposed on a base layer disposed on the side surface of the bank 116.

At least a part of the additional protrusion layer 481 may overlap the third electrode 121a disposed on the inclined portion 416a of the third planarization layer 415c.

The additional protrusion layer 481 may increase the amount of light that is emitted from the second organic layer 122a, is reflected by the third electrode 121a disposed on the inclined portion 416a of the third planarization layer 415c, and propagates to the outside of the display device 400.

Specifically, a part of the light reflected by the third electrode 121a disposed on the inclined portion 416a of the third planarization layer 415c propagates to at least one of the first sub-light-emitting area EA4-1, the second sub-light-emitting area EA4-2, and the third sub-light-emitting area EA4-3 of the first optical area DA1, which may improve the luminance of at least one sub-light-emitting area among the first sub-light-emitting area EA4-1, the second sub-light-emitting area EA4-2, and the third sub-light-emitting area EA4-3.

The second organic layer 122a and the fourth electrode 123a of the second light-emitting element 120a may be disposed on the bank 116, the additional protrusion layer 481, and the third electrode 121a.

The second organic layer 122a and the fourth electrode 123a may each be formed along the surface shapes of the additional protrusion layer 481 and the third electrode 121a in an intact manner.

Therefore, the second organic layer 122a and the fourth electrode 123a may include the plurality of convex areas and the plurality of concave areas in the inclined surface of the bank 116 and the concave portion 415 of the third planarization layer 415c.

As described above, the first optical area DA1 of the display device 400 further includes the additional protrusion layer 481, which may increase the luminance of at least one sub-light-emitting area among the first sub-light-emitting area EA4-1, the second sub-light-emitting area EA4-2, and the third sub-light-emitting area EA4-3 disposed in the first optical area DA1.

Meanwhile, in comparison with the normal area NA, the first optical area DA1 of the display device 400 further includes the additional protrusion layer 481, such that the luminance properties may be high even though the density of the light-emitting areas EA is lower than that of the normal area NA.

In addition, it is possible to improve the efficiency of the second light-emitting element 120a, suppress a degradation, and improve the lifespan of the second light-emitting element 120a.

However, the structure of the display device 400 according to the further embodiment of the present disclosure is not limited thereto. The additional protrusion layer 481 may also be disposed on the inclined portion of the bank 116 disposed in the normal area NA in accordance with design of luminance values.

Meanwhile, FIGS. 15 to 18 illustrate that the shape of each of the plurality of protrusions 480 is the shape convex from the top surface of the second planarization layer 115b. However, the present disclosure is not limited thereto.

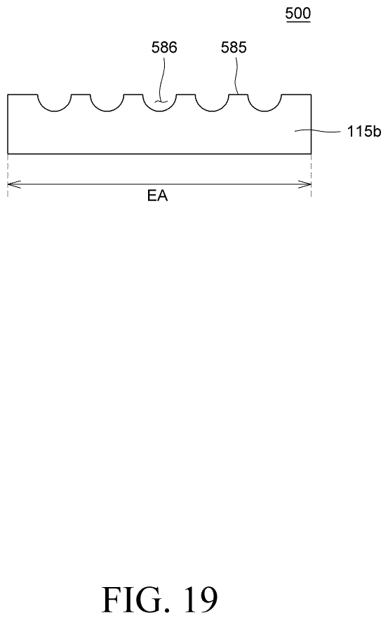

FIG. 19 is a cross-sectional view schematically illustrating shapes of a plurality of protrusions applied to a display device according to another further embodiment of the present disclosure.

With reference to FIG. 19, a plurality of convex areas 585 and a plurality of concave areas 586 may be disposed on at least a part of the top surface of the second planarization layer 115b included in a display device 500.

The plurality of convex areas 585 and the plurality of concave areas 586 of the second planarization layer 115b may be disposed in at least one light-emitting area EA disposed in the normal area NA and the first optical area DA1 of the display device 500.

However, the present disclosure is not limited thereto. The plurality of convex areas 585 and the plurality of concave areas 586 of the second planarization layer 115b may be disposed in at least one light-emitting area EA disposed in the first optical area DA1 of the display device 500.

The plurality of convex areas 585 and the plurality of concave areas 586 may be alternately disposed.

The plurality of concave areas 586 may have a semicircular shape in a cross-sectional view. However, the shapes of the plurality of concave areas 586 are not limited thereto, and the shape of each of the plurality of concave areas 586 may be various shapes such as a semi-elliptical shape and a polygonal shape.

The top surface of each of the plurality of convex areas 585 may have a flat shape. Specifically, the top surface of each of the plurality of convex areas 585 may have a structure extending in a direction perpendicular to a direction in which the first electrode 121 of the first light-emitting element 120 or the third electrode 121a of the second light-emitting element 120a is stacked on the second planarization layer 115b.

However, the cross-sectional shapes of the plurality of convex areas 585 are not limited thereto, and the shape of each of the plurality of convex areas 585 may be various shapes such as a semicircular shape, a semi-elliptical shape, or a polygonal shape.

As described above, the plurality of convex areas 585 and the plurality of concave areas 586 are disposed in at least one light-emitting area EA of the normal area NA and the first optical area DA1 of the display device 500, which may improve the efficiency in extracting light emitted from the first light-emitting element 120 and the first light-emitting element 120a disposed in the plurality of convex areas 585 and the plurality of concave areas 586.

Therefore, it is possible to improve the luminance of the normal area NA of the display device 500 and also improve the luminance of the first optical area DA1 in which the electronic optical device 170 is disposed.

In addition, the display device 500 may operate with low power consumption in terms of a reduction in power consumption.

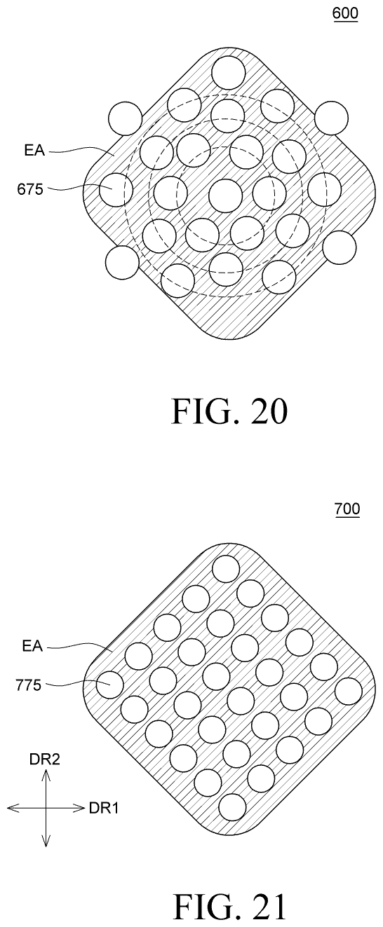

FIGS. 20 and 21 are views illustrating arrangement states of a plurality of patterns, a plurality of convex areas, or a plurality of protrusions disposed in a light-emitting area of a display device according to still another further embodiment of the present disclosure.

With reference to FIGS. 20 and 21, the normal area NA and the first optical area DA1 of a display device 600 may each include the plurality of light-emitting areas EA.

At least any one of the plurality of patterns, the plurality of convex areas, or the plurality of protrusions may be disposed in at least one light-emitting area EA disposed in each of the normal area NA and the first optical area DA1 of a display device 600, 700, or 800.

In the present disclosure, the plurality of patterns, the plurality of convex areas, or the plurality of protrusions included in the display device 600, 700, or 800 may be substantially equally configured. For convenience of description, in the following description, the plurality of patterns, the plurality of convex areas, or the plurality of protrusions will be referred to as a plurality of convex areas.

A plurality of convex areas 675 disposed in at least one light-emitting area EA disposed in each of the normal area NA and the first optical area DA1 of the display device 600 may be arranged in the Fibonacci sequence (Fibonacci numbers).

The Fibonacci sequence may be an infinite sequence in which a sum of the previous term (Fn-1) and the current term (Fn) is Fn-1+Fn.

The Fibonacci sequence has irregular intervals, such that the Fibonacci sequence may be repeated in 360 units instead of 60-degree intervals, and the Fibonacci sequence may reflect angles of 360 degrees or more. For example, in the Fibonacci sequence of one and one or more, a number exceeding 360 may be set to a reference angle deviation by subtracting 360 or a multiple of 360.

For example, the reference angle deviation according to the Fibonacci sequence of one and one or more may be set to 1, 1, 2, 3, 5, 8, 13, 21, 34, 55, 89, 144, 233, 17, 250, 267, 157, 64, 221, 285, 146, or the like.

A rainbow Mura having a radial shape and a circular ring Mura having a radial shape may occur on the reflected light emitted from the light-emitting area EA including the plurality of convex areas 675. However, the rotation angles of the plurality of convex areas 675 rotated at different angles for the respective light-emitting areas EA based on the irregular Fibonacci sequence are regularly set in accordance with the reference angle deviation in the unit of the light-emitting area EA, which may suppress the occurrence of a rainbow Mura and a circular ring Mura having a radial shape and improve the light extraction efficiency through the plurality of convex areas 675.

A plurality of convex areas 775 disposed in at least one light-emitting area EA disposed in each of the normal area NA and the first optical area DA1 of the display device 700 may be arranged regularly.

For example, based on one convex area 775, distances between the other convex areas 775 adjacent to one another in a first direction DR1 may be constant.

In addition, based on one convex area 775, distances between the other convex areas 775 adjacent to one another in a second direction DR2 intersecting the first direction DR1 may be constant.

As described above, it is possible to adjust the efficiency of the light-emitting elements in the light-emitting area EA disposed in the normal area NA and the first optical area DA1 by adjusting the arrangement of the plurality of convex areas 675 or 775.

In addition, the plurality of convex areas 675 or 775 included in the display device 600 or 700 according to another further embodiments of the present disclosure may change a propagation route of the light, which is emitted from the first organic layer 122 of the first light-emitting element 120 and the second organic layer 122a of the second light-emitting element 120a, toward the light emergent surface, and emit the light, which is totally reflected in the first light-emitting element 120 and the second light-emitting element 120a, toward the light emergent surface, thereby suppressing or minimizing a deterioration in light extraction efficiency caused by the light trapped in the first light-emitting element 120 and the second light-emitting element 120a.

In addition, the plurality of convex areas 675 or 775 are disposed in the normal area NA and the first optical area DA1 of the display device 600 or 700, such that the luminance of the normal area NA may be improved, and the luminance of the first optical area DA1 in which the electronic optical device 170 is disposed may also be improved.

The example embodiments of the present disclosure can also be described as follows:
According to an aspect of the present disclosure, there is provided a display device. The display device includes a substrate, a normal area comprising a first light-emitting area, an optical area surrounded by the normal area and comprising a second light-emitting area and a transmissive area, a planarization layer disposed on the substrate and disposed in the normal area and the optical area, a first light-emitting element disposed on the planarization layer in the first light-emitting area and comprising a first electrode, a first organic layer disposed on the first electrode, and a second electrode disposed on the first organic layer and a second light-emitting element disposed on the planarization layer in the second light-emitting area and comprising a third electrode, a second organic layer disposed on the third electrode, and a fourth electrode disposed on the second organic layer. The display device includes the fourth electrode of the second light-emitting element comprises at least one first convex area or at least one first concave area in the second light-emitting area.

A plurality of patterns may be disposed between the second organic layer and the fourth electrode in the second light-emitting area. The first convex area of the fourth electrode may be corresponding to an area in which the pattern is disposed. The first concave area of the fourth electrode may be corresponding to an area in which the pattern is not disposed.

A plurality of patterns may include beads.

The planarization layer may further include at least one third convex area in the first light-emitting area and at least one third concave area connected to the third convex area. The first electrode may include a fourth convex area in an area in which the third convex area is disposed and a fourth concave area in an area in which the third concave area is disposed. The first organic layer may include a fifth convex area in an area in which the third convex area is disposed and a fifth concave area in an area in which the third concave area is disposed.

A plurality of patterns may be disposed on a part of a top surface of the first organic layer in the first light-emitting area.

The second electrode may be disposed on the first organic layer and the pattern. The second electrode of the first light-emitting element may include a plurality of second convex areas or a plurality of second concave areas in the first light-emitting area. Heights of at least two second convex areas may be different from each other. Depths of at least two second concave areas may be different from each other.

The planarization layer may include at least one sixth convex area in the second light-emitting area and at least one sixth concave area connected to the sixth convex area. The third electrode may include a seventh convex area in an area in which the sixth convex area is disposed and a seventh concave area in an area in which the sixth concave area is disposed. The second organic layer may include a seventh convex area in an area in which the sixth convex area is disposed and a seventh concave area in an area in which the sixth concave area is disposed.

A plurality of patterns may be disposed on a part of a top surface of the second organic layer in the second light-emitting area.

The fourth electrode may be disposed on the second organic layer and the pattern. The fourth electrode of the second light-emitting element may include a plurality of first convex area or a plurality of first concave area in the second light-emitting area. Heights of at least two first convex areas may be different from each other. Depths of at least two first concave areas may be different from each other.

The display device may further include a first additional convex area configured to surround the second light-emitting area and a first additional concave area connected to the first additional convex area. The first additional convex area and the first additional concave area may be disposed in the transmissive area of the optical area or a non-light-emitting area of the optical area.

The first additional convex area and the first additional concave area may be disposed on a part of a top surface of the planarization layer. The second organic layer and the fourth electrode may be disposed in the first additional convex area and the first additional concave area.

The second organic layer may include a second additional convex area in an area in which the first additional convex area is disposed and a second additional concave area in an area in which the first additional concave area is disposed. The fourth electrode may include a third additional convex area in an area in which the first additional convex area is disposed and a third additional concave area in an area in which the first additional concave area is disposed.

The first additional convex area and the first additional concave area may not overlap a bank disposed on the planarization layer.

The planarization layer may include a first planarization layer and a second planarization layer disposed on the first planarization layer. The second planarization layer may include a concave portion and a protruding portion. The first electrode in the normal area may be disposed to partially cover the concave portion and the protruding portion and may be include a plurality of protrusions disposed between the first planarization layer and the first electrode in the concave portion of the first light-emitting area.

The first electrode, the first organic layer, and the second electrode in the concave portion of the first light-emitting area each may include a plurality of convex areas in an area in which the plurality of protrusions is disposed and a plurality of concave areas in an area in which the plurality of protrusions is not disposed.

The planarization layer may include a first planarization layer and a second planarization layer disposed on the first planarization layer. The second planarization layer comprises a concave portion and a protruding portion. The third electrode in the optical area may be disposed to partially cover the concave portion and the protruding portion and may include a plurality of protrusions disposed between the first planarization layer and the third electrode in the concave portion of the second light-emitting area.

The third electrode, the second organic layer, and the fourth electrode in the concave portion of the second light-emitting area each may include a plurality of convex areas in an area in which the plurality of protrusions are disposed and a plurality of concave areas in an area in which the plurality of protrusions are not disposed.

The display device may further include a bank configured to cover an edge of the third electrode and a part of the concave portion of the second planarization layer. An additional protrusion layer may be disposed on an inclined portion of the bank that overlaps at least a part of the concave portion.

The second organic layer and the fourth electrode may be disposed on the additional protrusion layer. The second organic layer and the fourth electrode each may include a convex area in an area in which a protrusion of the additional protrusion layer is disposed and a concave area in an area in which the protrusion of the additional protrusion layer is not disposed.

The second light-emitting area may include a first sub-light-emitting area, a second sub-light-emitting area configured to surround the first sub-light-emitting area and a third sub-light-emitting area configured to surround the second sub-light-emitting area. At least some of the plurality of protrusions may overlap the first sub-light-emitting area. At least a part of the additional protrusion layer may overlap the second sub-light-emitting area and the third sub-light-emitting area.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a normal area comprising a first light-emitting area;
an optical area surrounded by the normal area and comprising a second light-emitting area and a transmissive area;
a planarization layer disposed on the substrate and disposed in the normal area and the optical area;
a first light-emitting element disposed on the planarization layer in the first light-emitting area and comprising a first electrode, a first organic layer disposed on the first electrode, and a second electrode disposed on the first organic layer; and
a second light-emitting element disposed on the planarization layer in the second light-emitting area and comprising a third electrode, a second organic layer disposed on the third electrode, and a fourth electrode disposed on the second organic layer,
wherein the fourth electrode of the second light-emitting element comprises at least one first convex area or at least one first concave area in the second light-emitting area.

2. The display device of claim 1, comprising:
a plurality of patterns disposed between the second organic layer and the fourth electrode in the second light-emitting area,
wherein the first convex area of the fourth electrode corresponds to an area in which a pattern of the plurality of patterns is disposed, and
wherein the first concave area of the fourth electrode corresponds to an area in which the pattern of the plurality of patterns is not disposed.

3. The display device of claim 2, wherein the plurality of patterns comprises beads.

4. The display device of claim 1, wherein the planarization layer comprises:
at least one third convex area in the first light-emitting area; and
at least one third concave area connected to the third convex area,
wherein the first electrode comprises:
a fourth convex area in an area in which the third convex area is disposed; and
a fourth concave area in an area in which the third concave area is disposed, and
wherein the first organic layer comprises:
a fifth convex area in an area in which the third convex area is disposed; and
a fifth concave area in an area in which the third concave area is disposed.

5. The display device of claim 4, wherein a plurality of patterns is disposed on a part of a top surface of the first organic layer in the first light-emitting area.

6. The display device of claim 5, wherein the second electrode is disposed on the first organic layer and a pattern of the plurality of patterns,
wherein the second electrode of the first light-emitting element comprises a plurality of second convex areas or a plurality of second concave areas in the first light-emitting area,
wherein heights of at least two second convex areas are different from each other, and
wherein depths of at least two second concave areas are different from each other.

7. The display device of claim 1, wherein the planarization layer comprises:
at least one sixth convex area in the second light-emitting area; and
at least one sixth concave area connected to the sixth convex area,
wherein the third electrode comprises:
a seventh convex area in an area in which the sixth convex area is disposed; and
a seventh concave area in an area in which the sixth concave area is disposed, and
wherein the second organic layer comprises:
a seventh convex area in an area in which the sixth convex area is disposed; and
a seventh concave area in an area in which the sixth concave area is disposed.

8. The display device of claim 7, wherein a plurality of patterns is disposed on a part of a top surface of the second organic layer in the second light-emitting area.

9. The display device of claim 8, wherein the fourth electrode is disposed on the second organic layer and a pattern of the plurality of patterns,
wherein the fourth electrode of the second light-emitting element comprises a plurality of first convex area or a plurality of first concave area in the second light-emitting area,
wherein heights of at least two first convex areas are different from each other, and
wherein depths of at least two first concave areas are different from each other.

10. The display device of claim 1, further comprising:
a first additional convex area configured to surround the second light-emitting area; and
a first additional concave area connected to the first additional convex area,
wherein the first additional convex area and the first additional concave area are disposed in the transmissive area of the optical area or a non-light-emitting area of the optical area.

11. The display device of claim 10, wherein the first additional convex area and the first additional concave area are disposed on a part of a top surface of the planarization layer, and
wherein the second organic layer and the fourth electrode are disposed in the first additional convex area and the first additional concave area.

12. The display device of claim 11, wherein the second organic layer comprises:
a second additional convex area in an area in which the first additional convex area is disposed; and
a second additional concave area in an area in which the first additional concave area is disposed, and
wherein the fourth electrode comprises:
a third additional convex area in an area in which the first additional convex area is disposed; and
a third additional concave area in an area in which the first additional concave area is disposed.

13. The display device of claim 10, wherein the first additional convex area and the first additional concave area do not overlap a bank disposed on the planarization layer.

14. The display device of claim 1, wherein the planarization layer comprises:
a first planarization layer; and
a second planarization layer disposed on the first planarization layer,
wherein the second planarization layer comprises a concave portion and a protruding portion, and
wherein the first electrode in the normal area partially covers the concave portion and the protruding portion and comprises a plurality of protrusions disposed between the first planarization layer and the first electrode in the concave portion of the first light-emitting area.

15. The display device of claim 14, wherein the first electrode, the first organic layer, and the second electrode in the concave portion of the first light-emitting area each comprise:
a plurality of convex areas in an area in which the plurality of protrusions is disposed; and
a plurality of concave areas in an area in which the plurality of protrusions is not disposed.

16. The display device of claim 1, wherein the planarization layer comprises:
a first planarization layer; and
a second planarization layer disposed on the first planarization layer,
wherein the second planarization layer comprises a concave portion and a protruding portion, and
wherein the third electrode in the optical area partially covers the concave portion and the protruding portion and comprises a plurality of protrusions disposed between the first planarization layer and the third electrode in the concave portion of the second light-emitting area.

17. The display device of claim 16, wherein each of the third electrode, the second organic layer, and the fourth electrode in the concave portion of the second light-emitting area comprises:
a plurality of convex areas in an area in which the plurality of protrusions are disposed; and
a plurality of concave areas in an area in which the plurality of protrusions are not disposed.

18. The display device of claim 16, further comprising:
a bank configured to cover an edge of the third electrode and a part of the concave portion of the second planarization layer,
wherein an additional protrusion layer is disposed on an inclined portion of the bank that overlaps at least a part of the concave portion.

19. The display device of claim 18, wherein the second organic layer and the fourth electrode are disposed on the additional protrusion layer, and
wherein the second organic layer and the fourth electrode each comprise:
a convex area in an area in which a protrusion of the additional protrusion layer is disposed; and
a concave area in an area in which the protrusion of the additional protrusion layer is not disposed.

20. The display device of claim 18, wherein the second light-emitting area comprises:
a first sub-light-emitting area;
a second sub-light-emitting area surrounding the first sub-light-emitting area; and
a third sub-light-emitting area surrounding the second sub-light-emitting area,
wherein at least some of the plurality of protrusions overlap the first sub-light-emitting area, and
wherein at least a part of the additional protrusion layer overlaps the second sub-light-emitting area and the third sub-light-emitting area.
